(19) United States
(12) Patent Application Publication
(10) Pub. No.: US 2002/0179961 A1
(43) Pub. Date: Dec. 5, 2002

(54) Nonvolatile semiconductor memory device and manufacturing method of nonvolatile semiconductor memory device

(76) Inventors: Hiroaki Tsunoda, Yokkaichi-shi (JP); Hideyuki Kobayashi, Yokkaichi-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/156,142

(22) Filed: May 29, 2002

(30) Foreign Application Priority Data
May 29, 2001 (JP) P2001-160799

(51) Int. Cl. H01L 29/788

(52) U.S. Cl. 257/315

(57) ABSTRACT

There is provided a nonvolatile semiconductor memory device including an element region having a plurality of memory cells and an element isolating region. Here, the memory cell includes a channel region, a gate insulation film formed on the channel region, a floating gate electrode formed on the gate insulation film, a second gate insulation film formed on the floating gate electrode, a control gate electrode formed on the second gate insulation film, and source/drain regions formed to sandwich the channel region in a horizontal direction. The element isolating region includes: element isolating insulators formed to sandwich the channel region in a horizontal direction substantially perpendicular to the direction in which the source/drain regions sandwich the channel region; and an electric conductor passing inside the element isolating insulator in a horizontal direction substantially parallel to the direction in which the source/drain regions sandwich the channel region.

### CROSS REFERENCE TO RELATED APPLICATIONS

This application is based upon and claims the benefit of priority from the prior Japanese Patent Application No. 2001-160799 filed on May 29, 2001; the entire contents of which are incorporated herein by reference.

### BACKGROUND

1. Field of the Invention

The present invention relates to a nonvolatile semiconductor memory device which produces a nonvolatile memory state by accumulating an electric charge in a floating gate electrode and thereby, varying a threshold voltage and to a manufacturing method thereof, and more particularly to a nonvolatile semiconductor memory device suitable for reducing an influence that a write operation to each memory cell gives to a memory state of other memory cells and to a manufacturing method thereof.

2. Description of the Related Art

One example of a nonvolatile semiconductor memory device in a prior art will be explained with reference to FIG. 36. FIG. 36 is a view schematically showing one example of a sectional structure of the nonvolatile semiconductor memory device.

The surface of a semiconductor substrate 101, as shown in FIG. 36, is largely divided into element regions where first gate insulation films 102 exist and element isolating regions where element isolating insulation films 107 exist. A reference numeral 106 denotes a very thin silicon oxide film formed between the element isolating insulation film 107 and the semiconductor substrate 101.

The element regions are electrically isolated from each other in a horizontal direction on the drawing by the element isolating insulation films 107. In each of the element regions isolated by the element isolating insulation films 107, a region of the semiconductor substrate 101 directly under the first gate insulation film 102 is a channel region. A channel is formed in a perpendicular direction to the drawing in FIG. 36, and a source and a drain, though not shown in this sectional view, are formed respectively on a forward end and a backward end of the channel. Each memory cell (hereinafter, sometimes simply referred to as a cell) has one channel.

Polycrystalline silicon films 103 and 108 formed on the first gate insulation film 102 function as floating gate electrodes. A second gate insulation film 111 is formed on an upper surface and side surfaces of the polycrystalline silicon film 108 and surrounds the floating electrodes consisting of the polycrystalline silicon films 103 and 108 to bring them in an electrically floated state. Incidentally, the second gate insulation film 111 has a three-layered structure of, for example, an oxide film, a nitride film, an oxide film from a bottom layer.

On the second gate insulation film 111, formed is a polycrystalline silicon film 112, on which a tungsten silicide film 113 is further formed. The polycrystalline silicon film 112 and the tungsten silicide film 113 function as control gate electrodes.

Specifically, the polycrystalline silicon film 112 and the tungsten silicide film 113 are given a relatively high voltage, which is tunneled through the second gate insulation film 111 so that an electric charge is accumulated in the polycrystalline silicon films 103 and 108 which are the floating gate electrodes and a memory state is produced. In order to read this, the polycrystalline silicon film 112 and the tungsten silicide film 113 are given a relatively low voltage as a read voltage, and conductivity/nonconductivity in this state between the source and the drain sandwiching the channel corresponds to a memory state. Note that the polycrystalline silicon film 112 and the tungsten silicide film 113 in FIG. 36, which extend in a horizontal direction on the drawing, also function as gate wiring.

A silicon oxide film 114, a silicon oxide film 115, a silicon nitride film 116, and a silicon oxide film 119 are formed on the tungsten silicide film 113 in this order. A tungsten film 122 as wiring is formed in the silicon oxide film 119, being selectively positioned on an upper surface side of the silicon oxide film 119 and having a certain depth in it, and a titanium film 121 is formed as a barrier metal between the tungsten film 122 and the silicon oxide film 119.

In the nonvolatile semiconductor memory device as explained above, when the amount of the electric charge accumulated in the polycrystalline silicon films 103 and 108 which are the floating gate electrodes is made to be three-valued or more, a storable amount for each cell exceeds one bit, which makes it possible to increase a storable information amount. Moreover, other than this method, promotion of microfabrication to realize high integration is also adoptable as a method of increasing the storable information amount.

When the multi-valued memory and high integration described above are adopted, an adverse effect given to an adjacent cell in carrying out a write operation to a cell becomes distinguished. This will be explained with reference to FIG. 37. FIG. 37 is a graph showing threshold voltage distributions of the number of cells in a semiconductor memory device having a plurality of cells.

In FIG. 37, the distribution of the cells in a certain memory state is indicated by “certain data” and the distribution of the cells in a different memory state is indicated by “different data”. As shown in FIG. 37, the “certain data” is stored as a state where a threshold voltage is relatively low and the “different data” is stored as a state in which a threshold voltage is relatively high. As shown in FIG. 37, the threshold voltage distributions of the number of cells are clearly separated from each other in an ideal case so that any read cell is not mistakenly read as other data.

However, when the “certain data” is written to a cell adjacent to a cell to which the “different data” is written, this generally influences the cell to which the “different data” is written. This is because a write voltage for the “certain data” transmits due to an electrostatic capacitance that the element isolating insulation film 107 between the cells has, thereby changing an electric charge amount accumulated in a floating gate electrode of the cell having the “different data”, which further changes its threshold voltage. As a result of this change in the threshold voltage, an actual threshold voltage distribution of the cell having the “different data” is widened as shown in FIG. 37 as a whole semiconductor memory device having the plural cells.

This widening of the threshold voltage distribution, however, is not significant when mean threshold voltages of the “certain data” and the “different data” are made different to a sufficiently large extent. Moreover, as long as such a change in the threshold voltage is caused by the electrostatic capacitance that the element isolating insulation film 107 between the cells has, its influence is smaller as its capacitance value is smaller, and therefore, the element isolating insulation film 107 may be formed not in a highly integrated manner but in a manner it has a large width in order to sufficiently decrease the capacitance value.

When the multi-valued memory and the high integration as described above are promoted, however, the difference in the mean threshold voltage between the “certain data” and the “different data” has to be set relatively small, and moreover, the electrostatic capacitance of the element isolating insulation film 107 between the cells becomes larger as the element isolating insulation film 107 is made narrower. Therefore, when the distribution in the “actual case” shown in FIG. 37 is the worst, this distribution overlaps the threshold voltage distribution of the cell having the “different data” to cause an error in read data. Even when the distributions do not overlap each other soon after the write operation, they might possibly overlap each other with the elapse of time, considering that the electric charge accumulated in the floating gate electrode generally has a property of being slightly lost with the elapse of time, which lowers reliability as a semiconductor memory device.

### SUMMARY

A nonvolatile semiconductor memory device according to an embodiment of the present invention is a nonvolatile semiconductor memory device comprising an element region having a plurality of memory cells and an element isolating region to electrically isolate the memory cells from each other. Each of the memory cells mentioned here comprises: a channel region; a gate insulation film formed on the channel region; a floating gate electrode formed on the gate insulation film; a second gate insulation film formed on the floating gate electrode; a control gate electrode formed on the second gate insulation film; and source/drain regions formed to sandwich the channel region in a horizontal direction. The element isolating region comprises: element isolating insulators formed to sandwich the channel region in a horizontal direction substantially perpendicular to the direction in which the source/drain regions sandwich the channel region; and an electric conductor passing inside the element isolating insulator in a horizontal direction substantially parallel to the direction in which the source/drain regions sandwich the channel region.

A manufacturing method of a nonvolatile semiconductor memory device according to an embodiment of the present invention comprises: forming on a semiconductor substrate an insulation film to be a gate insulation film; forming a trench on the semiconductor substrate; forming a second insulation film on a bottom wall and side walls of the formed trench; forming an electric conductive film in the trench on which the second insulation film is formed; forming a third insulation film to cover an upper surface of the electric conductive film; forming on the insulation film a second electric conductive film to be a floating gate electrode; forming on the second electric conductive film a fourth insulation film to be a second gate insulation film; forming on the fourth insulation film a third electric conductive film to be a control gate electrode; and forming source/drain regions under the insulation film.

### BRIEF DESCRIPTION OF THE DRAWINGS

Embodiments of the present invention will be described with reference to the drawings, which are provided only for the illustrative purpose and are not intended to limit the present invention in any respects.

FIG. 1 is a plan view showing a schematic structure of a nonvolatile semiconductor memory device in an embodiment of the present invention.

FIG. 2 is a schematic sectional view taken along the line A-Aa in FIG. 1.

FIG. 3 is a schematic sectional view taken along the line B-Ba in FIG. 1;

FIG. 4A and FIG. 4B are process views as one example of manufacturing the semiconductor memory device having the structure shown in FIG. 2 and FIG. 3.

FIG. 5A and FIG. 5B, which are views subsequent to FIG. 4A and FIG. 4B, are process views as one example of manufacturing the semiconductor memory device having the structure shown in FIG. 2 and FIG. 3.

FIG. 6A and FIG. 6B, which are views subsequent to FIG. 5A and FIG. 5B, are process views as one example of manufacturing the semiconductor memory device having the structure shown in FIG. 2 and FIG. 3.

FIG. 7A and FIG. 7B, which are views subsequent to FIG. 6A and FIG. 6B, are process views as one example of manufacturing the semiconductor memory device having the structure shown in FIG. 2 and FIG. 3.

FIG. 8A and FIG. 8B, which are views subsequent to FIG. 7A and FIG. 7B, are process views as one example of manufacturing the semiconductor memory device having the structure shown in FIG. 2 and FIG. 3.

FIG. 9A and FIG. 9B, which are views subsequent to FIG. 8A and FIG. 8B, are process views as one example of manufacturing the semiconductor memory device having the structure shown in FIG. 2 and FIG. 3.

FIG. 10A and FIG. 10B, which are views subsequent to FIG. 9A and FIG. 9B, are process views as one example of manufacturing the semiconductor memory device having the structure shown in FIG. 2 and FIG. 3.

FIG. 11A and FIG. 11B, which are views subsequent to FIG. 10A and FIG. 10B, are process views as one example of manufacturing the semiconductor memory device having the structure shown in FIG. 2 and FIG. 3.

FIG. 12A and FIG. 12B, which are views subsequent to FIG. 11A and FIG. 11B, are process views as one example of manufacturing the semiconductor memory device having the structure shown in FIG. 2 and FIG. 3.

FIG. 13A and FIG. 13B, which are views subsequent to FIG. 12A and FIG. 12B, are process views as one example of manufacturing the semiconductor memory device having the structure shown in FIG. 2 and FIG. 3.

FIG. 14A and FIG. 14B, which are views subsequent to FIG. 13A and FIG. 13B, are process views as one example of manufacturing the semiconductor memory device having the structure shown in FIG. 2 and FIG. 3.

FIG. 15A and FIG. 15B, which are views subsequent to FIG. 14A and FIG. 14B, are process views as one example of manufacturing the semiconductor memory device having the structure shown in FIG. 2 and FIG. 3.

FIG. 16A and FIG. 16B, which are views subsequent to FIG. 15A and FIG. 15B, are process views as one example of manufacturing the semiconductor memory device having the structure shown in FIG. 2 and FIG. 3.

FIG. 17A and FIG. 17B, which are views subsequent to FIG. 16A and FIG. 16B, are process views as one example of manufacturing the semiconductor memory device having the structure shown in FIG. 2 and FIG. 3.

FIG. 18A and FIG. 18B, which are views subsequent to FIG. 17A and FIG. 17B, are process views as one example of manufacturing the semiconductor memory device having the structure shown in FIG. 2 and FIG. 3.

FIG. 19A and FIG. 19B, which are views subsequent to FIG. 18A and FIG. 18B, are process views as one example of manufacturing the semiconductor memory device having the structure shown in FIG. 2 and FIG. 3.

FIG. 20A and FIG. 20B, which are views subsequent to FIG. 19A and FIG. 19B, are process views as one example of manufacturing the semiconductor memory device having the structure shown in FIG. 2 and FIG. 3.

FIG. 21A and FIG. 21B, which are views subsequent to FIG. 20A and FIG. 20B, are process views as one example of manufacturing the semiconductor memory device having the structure shown in FIG. 2 and FIG. 3.

FIG. 22A and FIG. 22B, which are views subsequent to FIG. 21A and FIG. 21B, are process views as one example of manufacturing the semiconductor memory device having the structure shown in FIG. 2 and FIG. 3.

FIG. 23A and FIG. 23B, which are views subsequent to FIG. 22A and FIG. 22B, are process views as one example of manufacturing the semiconductor memory device having the structure shown in FIG. 2 and FIG. 3.

FIG. 24A and FIG. 24B, which are views subsequent to FIG. 23A and FIG. 23B, are process views as one example of manufacturing the semiconductor memory device having the structure shown in FIG. 2 and FIG. 3.

FIG. 25A and FIG. 25B, which are views subsequent to FIG. 24A and FIG. 24B, are process views as one example of manufacturing the semiconductor memory device having the structure shown in FIG. 2 and FIG. 3.

FIG. 26A and FIG. 26B, which are views subsequent to FIG. 25A and FIG. 25B, are process views as one example of manufacturing the semiconductor memory device having the structure shown in FIG. 2 and FIG. 3.

FIG. 27A and FIG. 27B, which are views subsequent to FIG. 26A and FIG. 26B, are process views as one example of manufacturing the semiconductor memory device having the structure shown in FIG. 2 and FIG. 3.

FIG. 28A and FIG. 28B, which are views subsequent to FIG. 27A and FIG. 27B, are process views as one example of manufacturing the semiconductor memory device having the structure shown in FIG. 2 and FIG. 3.

FIG. 29A and FIG. 29B, which are views subsequent to FIG. 28A and FIG. 28B, are process views as one example of manufacturing the semiconductor memory device having the structure shown in FIG. 2 and FIG. 3.

FIG. 30A and FIG. 30B, which are views subsequent to FIG. 29A and FIG. 29B, are process views as one example of manufacturing the semiconductor memory device having the structure shown in FIG. 2 and FIG. 3.

FIG. 31A and FIG. 31B, which are views subsequent to FIG. 30A and FIG. 30B, are process views as one example of manufacturing the semiconductor memory device having the structure shown in FIG. 2 and FIG. 3.

FIG. 32A and FIG. 32B, which are views subsequent to FIG. 31A and FIG. 31B, are process views as one example of manufacturing the semiconductor memory device having the structure shown in FIG. 2 and FIG. 3.

FIG. 33A and FIG. 33B, which are views subsequent to FIG. 32A and FIG. 32B, are process views as one example of manufacturing the semiconductor memory device having the structure shown in FIG. 2 and FIG. 3.

FIG. 34A and FIG. 34B, which are views subsequent to FIG. 33A and FIG. 33B, are process views as one example of manufacturing the semiconductor memory device having the structure shown in FIG. 2 and FIG. 3.

FIG. 35 is a graph showing, in comparison with a prior art, a threshold voltage distribution of the number of cells in the semiconductor memory device having a plurality of cells, which is the embodiment shown in FIG. 2 and FIG. 3.

FIG. 36 is a view schematically showing one example of a sectional structure of a nonvolatile semiconductor memory device in the prior art.

FIG. 37 is a graph showing a threshold voltage distribution of the number of cells in a semiconductor memory device having a plurality of cells (an example in the prior art).

### DETAILED DESCRIPTION

### Explanation of Embodiments

According to a nonvolatile semiconductor memory device in embodiments of the present invention, when a write operation to a memory cell is carried out, since an electric conductor exists inside an element isolating insulator in an element isolating region which isolates memory cells from each other, an act of a write voltage in a direction of an adjacent memory cell presents itself as capacitive coupling to this electric conductor and as a result, an influence of the write voltage transmits little to the adjacent cell. Therefore, an adverse effect that the write operation to each memory cell gives to a memory state of other memory cells is reduced and change in threshold voltages of the other memory cells due to the write operation to each memory cell is suppressed. Consequently, malfunction prevention and reliability enhancement as a memory cell are realized.

As an implementation mode for carrying out the present invention, a floating gate electrode is capable of maintaining an amount of a held electric charge which is to form a memory state, in such a manner that it corresponds to three memory states or more. The multi-valued memory inevitably requires the range of the threshold voltage distribution to be narrow and this is realized in the nonvolatile semiconductor memory device according to the embodiments of the present invention.

Moreover, the nonvolatile semiconductor memory device as an implementation mode for carrying out the present invention further comprises a contact to the aforesaid electric conductor which is disposed in contact with the electric conductor and which is to apply a certain voltage to the electric conductor. The existence of the contact enables a desired voltage to be applied to the electric conductor.

Furthermore, as an implementation mode for carrying out the present invention, the electric conductor is made to be a ground potential. This enables a certain voltage to be given to the electric conductor in the easiest manner.

Moreover, as an implementation mode for carrying out the present invention, the electric conductor is polycrystalline silicon of a first conductivity type or a second conductivity type.

Furthermore, as an implementation mode for carrying out the present invention, the electric conductor is tungsten or aluminum.

Moreover, as an implementation mode for carrying out the present invention, the electric conductor is metal silicide.

As described above, the polycrystalline silicon of the first conductivity type or the second conductivity type, a metal such as tungsten and aluminum, and furthermore, the metal silicide are used as the electric conductor so that necessary electric conductivity, easiness in handling (easiness in manufacturing), and so on can be obtained.

Furthermore, as an implementation mode for carrying out the present invention, the aforesaid element isolating insulator is silicon oxide. This realizes good element isolating.

Moreover, as an implementation mode for carrying out the present invention, the element isolating insulator is formed in a trench. This contributes to high integration.

Moreover, based on a manufacturing method of the nonvolatile semiconductor memory device according to embodiments of the present invention, the trench is formed, and a second insulation film and a third insulation film as the element isolating insulators are formed in it, and furthermore, an electric conductive film can be formed, being surrounded by these insulation films, so that the nonvolatile semiconductor memory device according to the embodiments of the present invention can be manufactured. This makes it possible to manufacture a nonvolatile semiconductor memory device in which an adverse effect that a write operation to each memory cell gives to a memory state of other memory cells is reduced and malfunction prevention and reliability enhancement are realized.

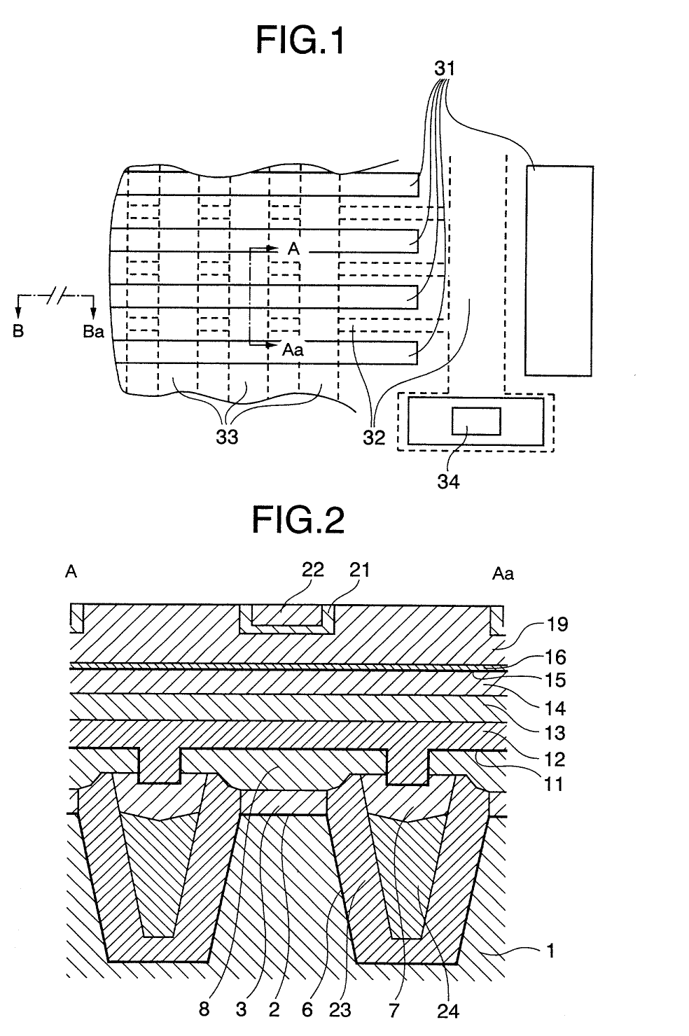

An embodiment of the present invention will be explained below with reference to the drawings. FIG. 1 is a plan view showing a schematic structure of the nonvolatile semiconductor memory device according to the embodiment of the present invention. As shown in FIG. 1, this nonvolatile semiconductor memory device includes element regions 31, and a plurality of memory cells based on MOS transistors and other cells exist in the element regions 31.

The element regions 31 have long regions extending in a direction of the plural cells whose drains and sources are connected, and between these regions, there exist element isolating regions which electrically isolate the cells from each other. As shown in FIG. 1, electric conductors 32 are formed, being embedded in the element isolating regions, and a desired voltage can be applied to these electric conductors 32 by a contact 34.

Incidentally, a desired voltage which is generated in a different portion in the same semiconductor chip (namely, this nonvolatile semiconductor memory device) and a ground potential may be introduced to the contact 34 by metal wiring, or metal wiring connected to a pad for outside connection may be disposed in order to give a desired voltage and a ground potential to the contact 34 from an external part.

The gate wiring, which is denoted by the reference numeral 33, is formed to cross the plural cells which exist in the element regions 31 and whose drains and sources are connected, and further to connect gates of the cells adjacent to each other across the element isolating regions as shown in FIG. 1.

FIG. 2 is a schematic sectional view taken along the line A-Aa in FIG. 1. In FIG. 2, a region where a first gate insulation film 2 exists corresponds to the element region 31 in FIG. 1, a polycrystalline silicon film 24 corresponds to the electric conductor 32 in FIG. 1, and a polycrystalline silicon film 12 and a tungsten silicide film 13 correspond to the gate wiring 33 in FIG. 1.

Specifically, the surface of a semiconductor substrate 1 is largely divided into the element regions where the first gate insulation films 2 exist and the element isolating regions where silicon oxide films 7 and 23 and the polycrystalline silicon films 24 exist. The reference numeral 6 denotes a very thin silicon oxide film formed between the silicon oxide film 23 and the semiconductor substrate 1.

The element regions are electrically isolated from each other in a horizontal direction on the drawing by the silicon oxide films 7 and 23 and the polycrystalline silicon films 24. In each of the element regions isolated by the silicon oxide films 7 and 23 and the polycrystalline silicon films 24, a region of the semiconductor substrate 1 directly under the first gate insulation film 2 becomes a channel region. A channel is formed in a perpendicular direction to the drawing in FIG. 2, and a source and a drain, though not shown in this sectional view, are formed at a forward end and a backward end of the channel respectively. Each cell has one channel.

Polycrystalline silicon films 3 and 8 formed on the first gate insulation film 2 function as floating gate electrodes. A second gate insulation film 11 is formed on an upper surface and side surfaces of the polycrystalline silicon film 8, surrounding the floating gate electrodes consisting of the polycrystalline silicon films 8 and 3 to bring them into an electrically floated state. Incidentally, the second gate insulation film 11 has a three-layered structure consisting of, for example, an oxide film, a nitride film, an oxide film from a bottom layer.

On the second gate insulation film 11, formed is the polycrystalline silicon film 12, on which the tungsten silicide film 13 is further formed. The polycrystalline silicon film 12 and the tungsten silicide film 13 function as control gate electrodes.

Specifically, the polycrystalline silicon film 12 and the tungsten silicide film 13 are given a relatively high voltage, which is tunneled through the second gate insulation film 11, so that an electric charge is accumulated in the polycrystalline silicon films 3 and 8 which are the floating gate electrodes and a memory state is produced. In order to read this, the polycrystalline silicon film 12 and the tungsten silicide film 13 are given a read voltage which is a relatively low voltage, and conductivity/nonconductity in this state between the source and the drain sandwiching the channel corresponds to a memory state. Incidentally, in FIG. 2, the polycrystalline silicon film 12 and the tungsten silicide film 13, which extend in a horizontal direction on the drawing, function also as the gate wiring as described above.

A silicon oxide film 14, a silicon oxide film 15, a silicon nitride film 16, and a silicon oxide film 19 are formed on the tungsten silicide film 13 from the bottom in this order. A tungsten film 22 as wiring is formed in the silicon oxide film 19, being selectively positioned on an upper surface side of the silicon oxide film 19 and having a certain depth in it. A titanium film 21 as a barrier metal is formed between the tungsten film 22 and the silicon oxide film 19.

As explained above, other than the silicon oxide films 7 and 23, the polycrystalline silicon film 24 as an electric conductor surrounded by these silicon oxide films 7 and 23 and formed in a parallel direction to the channel is provided between memory cells adjacent to each other across the element isolating region in the nonvolatile semiconductor memory device in this embodiment. This causes an act of the write voltage in a direction to an adjacent cell to present itself as capacitive coupling to the polycrystalline silicon film 24 which can be set at a fixed voltage when the write operation is performed, and as a result, little influence of the write voltage transmits to the adjacent cell.

Consequently, change in the threshold voltage of other memory cells due to the write operation to each memory cell is suppressed, thereby realizing malfunction prevention and reliability enhancement as a memory cell.

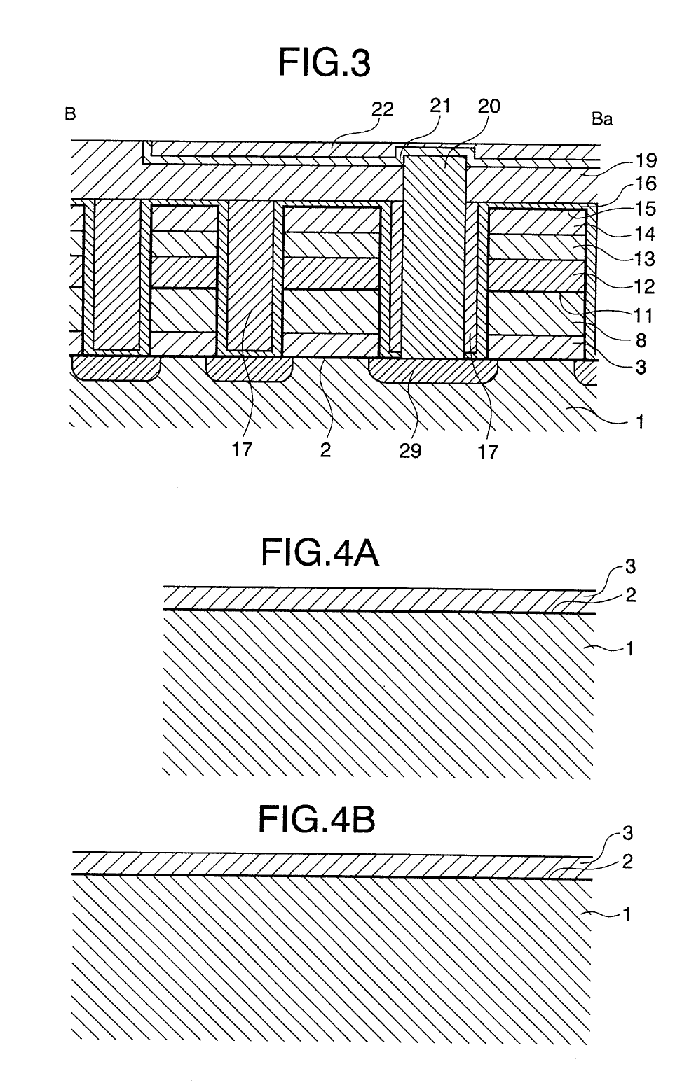

FIG. 3, which is shown for reference, is a schematic sectional view taken along the line B-Ba in FIG. 1 and is a view schematically showing a vertical cross section in the direction in which the channel of the memory cell is formed, the vertical cross section including a contact portion to a source or a drain of a MOS transistor in the element region 31. In FIG. 3, the same reference numerals are used to designate the constituent elements already explained.

As shown in FIG. 3, the first gate insulation film 2 is formed on the semiconductor substrate 1 of each cell and the channel is directly under the first gate insulation film 2 of each cell. Between the channel and adjacent cells connected thereto, source/drain regions 29 are formed to sandwich this channel. By the source/drain regions 29, for example, sources and drains of the cells are connected in series along the element region as shown in FIG. 3. A source or drain region of one cell among the cells connected in series is connected to the tungsten film 22 as the wiring via the titanium film 21 under which a polycrystalline silicon film 20 for a contact is formed.

Incidentally, each of areas on the source/drain regions along the element region, that is spaces between elements, is filled with the silicon oxide film 15, the silicon nitride film 16, and an insulation film (BPSG: borophospho silicate glass) 17.

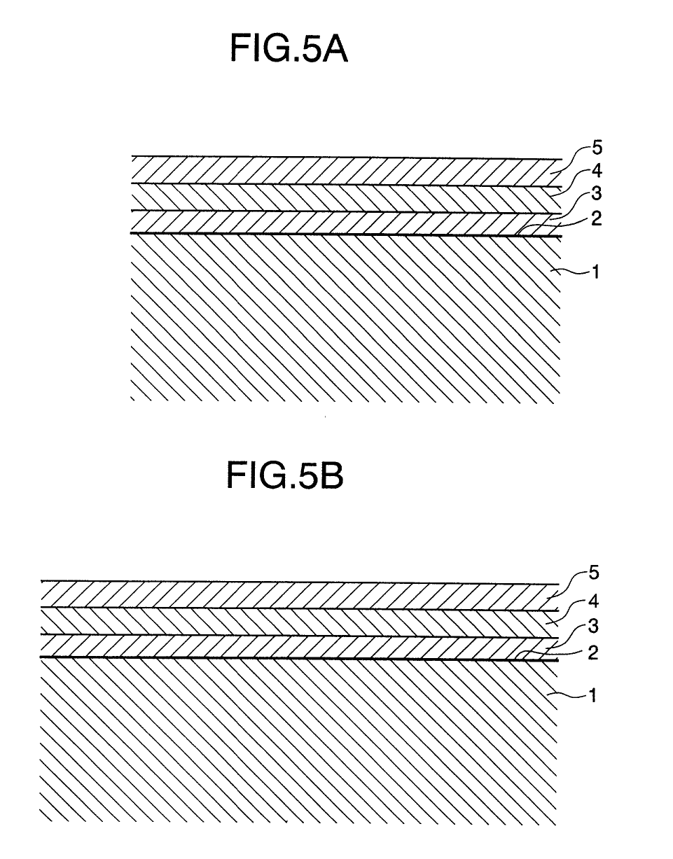

Next, manufacturing processes of the semiconductor memory device having the structure shown in FIG. 2 and FIG. 3 will be explained with reference to FIG. 4A and FIG. 4B to FIG. 34A and FIG. 34B. FIG. 4A and FIG. 4B to FIG. 34A and FIG. 34B are views showing one example of manufacturing processes of the semiconductor memory device having the structure shown in FIG. 2 and FIG. 3, and each of the drawings with the suffix A corresponds to the portion shown in FIG. 2 and each of the drawings with the suffix B corresponds to the portion shown in FIG. 3.

First, as shown in FIG. 4A and FIG. 4B, the first gate insulation film (for example, an oxide film) 2 having a thickness of, for example, 8 nm is formed on the semiconductor substrate 1, and the polycrystalline silicon film 3 having a thickness of, for example, 60 nm is further deposited on it, for example, by a pressure-reduced CVD method (chemical vapor deposition method).

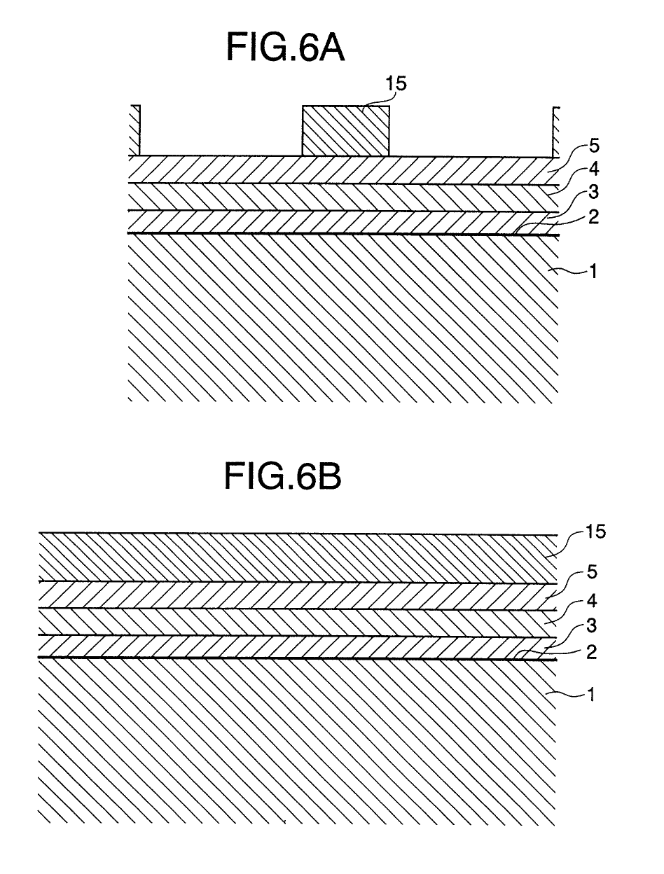

Next, as shown in FIG. 5A and FIG. 5B, a silicon nitride film 4 having a thickness of, for example, 70 nm is formed, for example, by the pressure-reduced CVD method and successively a silicon oxide film 5 having a thickness of, for example, 230 nm is further deposited on it.

Next, hydrogen fuel oxidation processing is performed at 850° C. for 30 minutes, and furthermore, a photoresist 15 is applied on the surface and is patterned to a predetermined pattern using a photo-etching technique as shown in FIG. 6A and FIG. 6B.

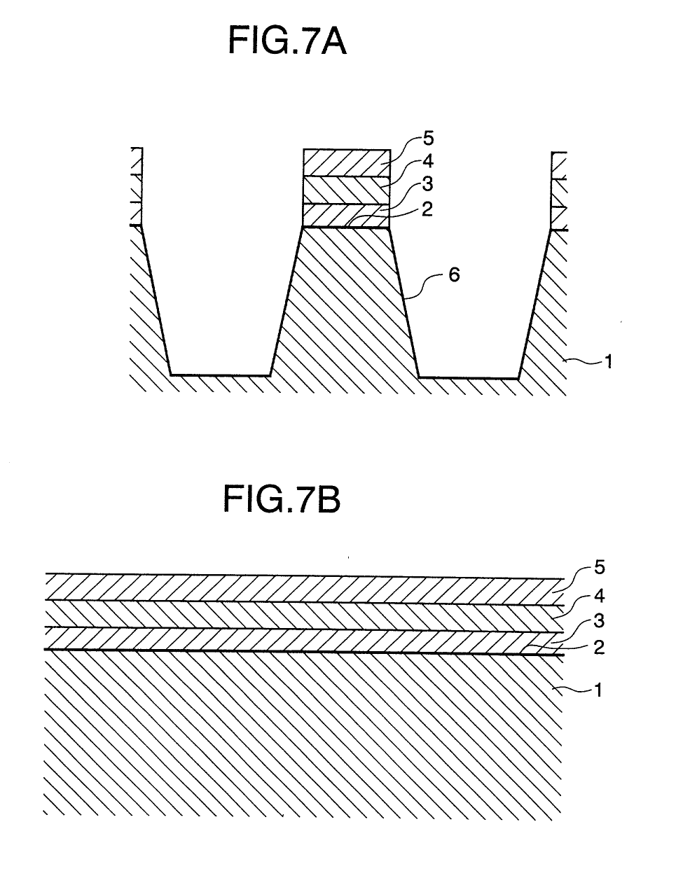

Next, with the patterned resist 15 used as a mask, the silicon nitride film 4 and the silicon oxide film 5 are processed and removed using, for example, an RIE method (reactive ion etching method), and furthermore, the resist 15 is removed, for example, by an O₂ plasma treatment and using a mixed solution of sulfuric acid and a hydrogen peroxide solution. Then, the polycrystalline silicon film 3 is processed, for example, by the RIE method, and the first gate insulation film 2 and the semiconductor substrate 1 are further processed in a similar method to form a silicon groove (trench) as shown in FIG. 7A and FIG. 7B. The silicon oxide film 6 having a thickness of, for example, about 6 nm is formed on an inner wall of the silicon groove by thermal processing in an oxide atmosphere, for example, at 1000° C.

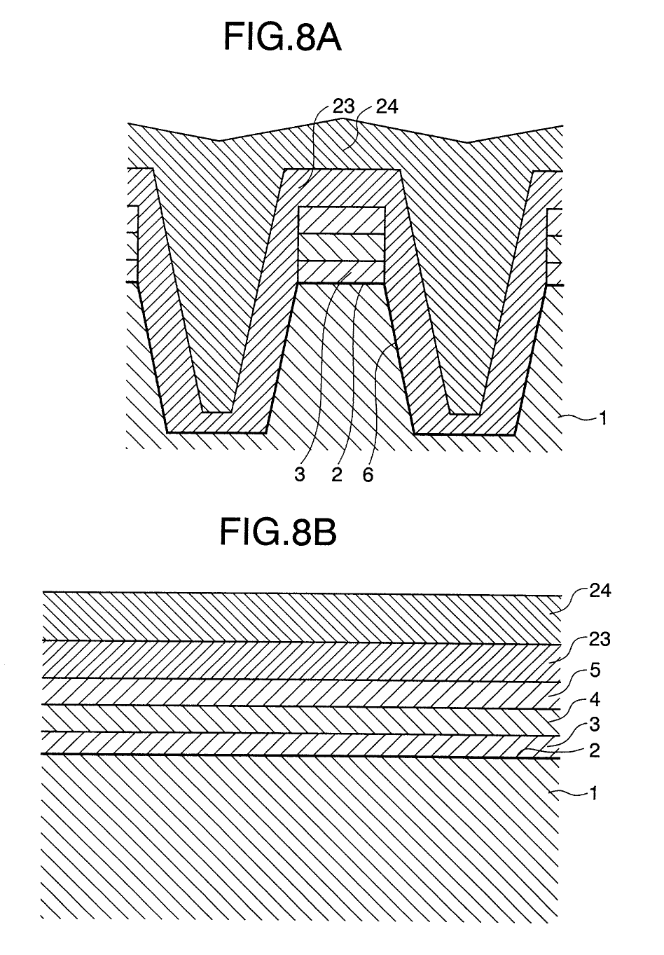

Next, the silicon oxide film 23 having a thickness of 50 nm is subsequently deposited, for example, by the pressure-reduced CVD method, and the polycrystalline silicon film 24 to which, for example, phosphor is added is further deposited to be 200 nm in thickness, for example, by the pressure-reduced CVD method as shown in FIG. 8A and FIG. 8B. Incidentally, instead of forming this polycrystalline silicon film 24 here, which works as an electric conductor in the element isolating insulator as explained in FIG. 2, a tungsten film or an aluminum film may be formed by a thermal CDV method, or a metal silicide film such as WSi_{X} and TiSi_{X} may be formed in a similar manner.

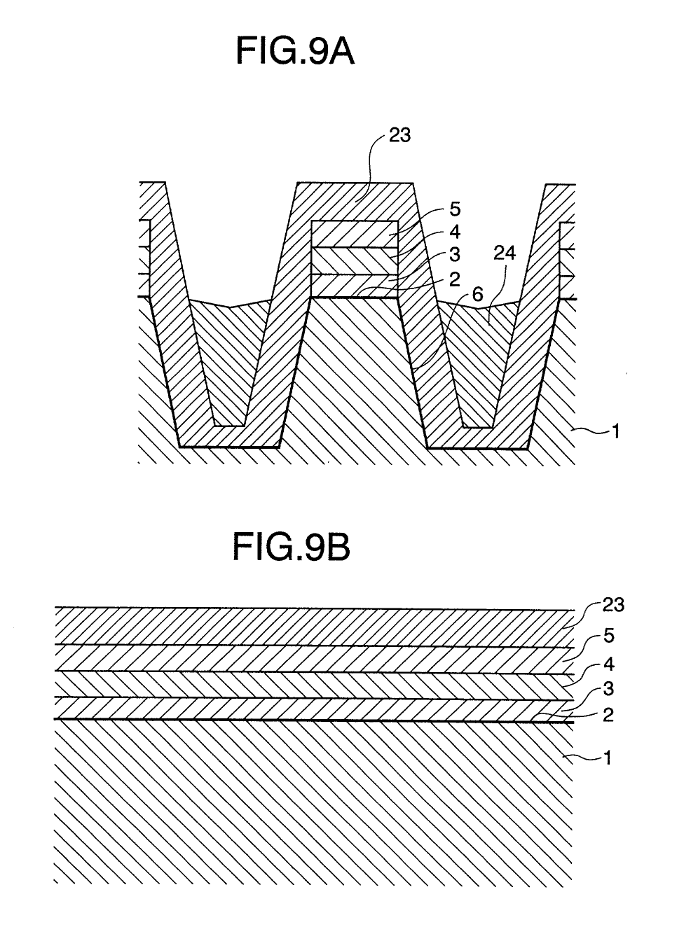

Next, as shown in FIG. 9A and FIG. 9B, the entire surface of the polycrystalline silicon film 24 is etched, for example, by a CDE method (chemical dry etching method), with only a portion thereof in the trench left. At this time, an upper surface of the polycrystalline silicon film 24 is preferably made lower than an upper surface of the polycrystalline silicon film 3, for the convenience in carrying out subsequent processes.

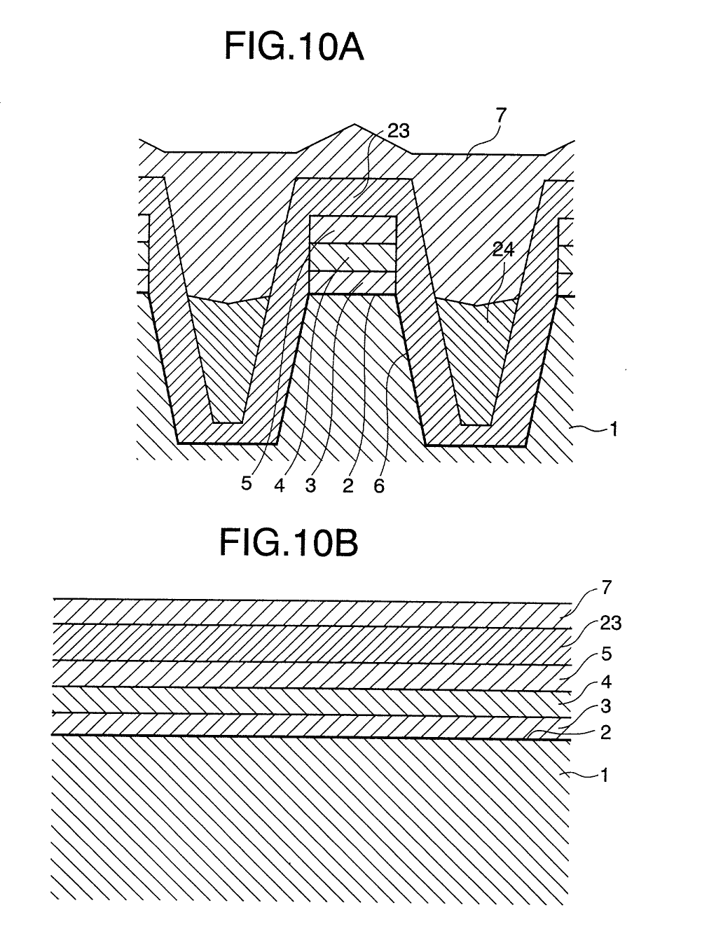

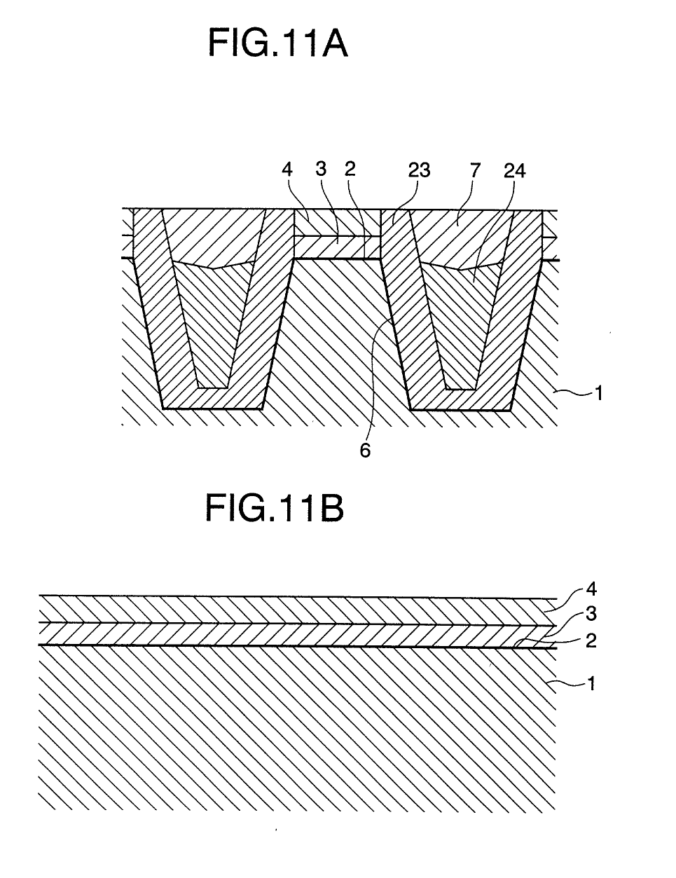

Next, as shown in FIG. 10A and FIG. 10B, the silicon oxide film (USG film: undoped silicate glass film) 7 having a thickness of 200 nm is deposited, for example, by an HDP method (high density plasma method). Then, as shown in FIG. 11A and FIG. 11B, the silicon oxide film 7 and so on are shaved to be flattened, for example, by a CMP method (chemical mechanical polishing method) until the silicon nitride film 4 is exposed.

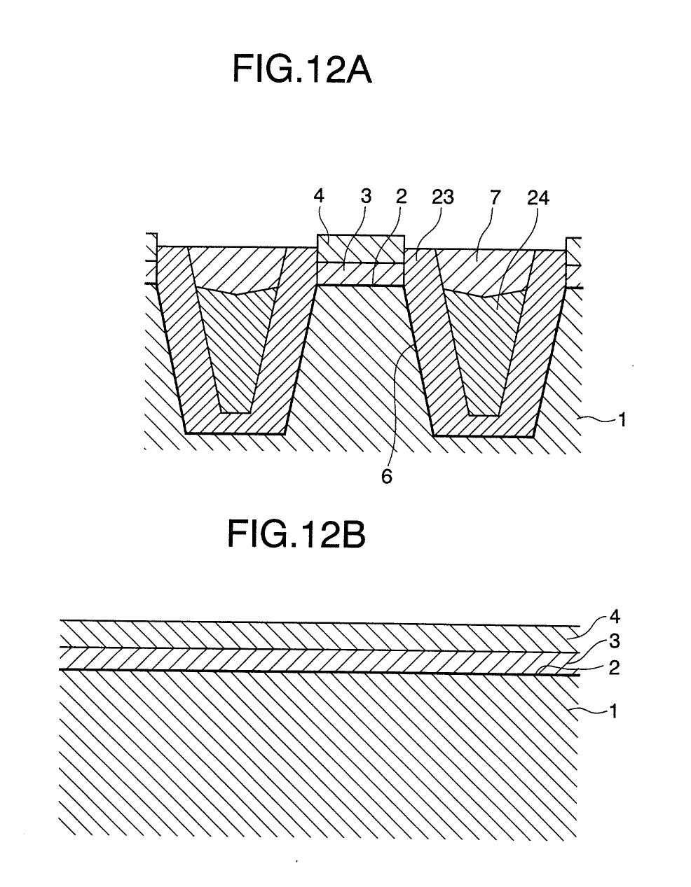

Next, as shown in FIG. 12A and FIG. 12B, the silicon oxide film 7 and so on are etched by about 10 nm, for example, by a buffered hydrofluoric acid (buffered-HF) treatment. Then, the silicon nitride film 4 is selectively removed by a phosphoric acid treatment, for example, at 150° C. for 40 minutes.

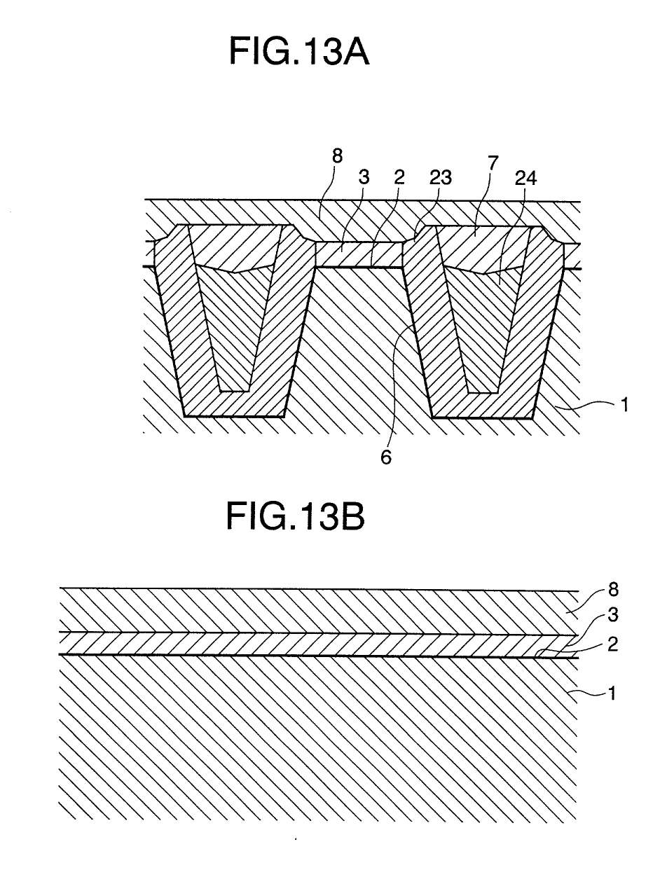

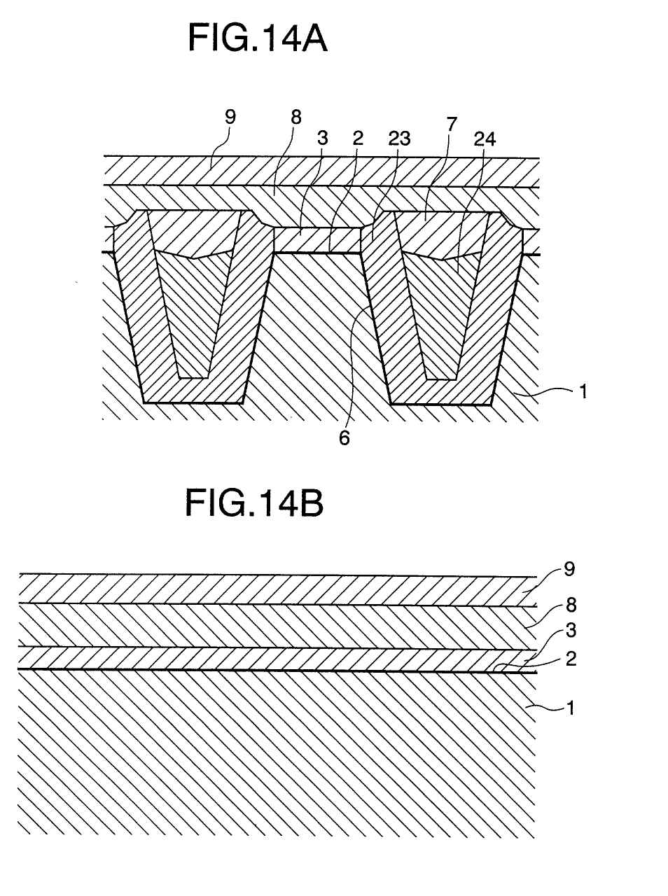

Next, as shown in FIG. 13A and FIG. 13B, the polycrystalline silicon film 8 having a thickness of 100 nm is deposited, for example, by the pressure-reduced CVD method. Then, as shown in FIG. 14A and FIG. 14B, a silicon oxide film 9 which works as a mask material is deposited to be 230 nm in thickness, for example, by the pressure-reduced CVD method.

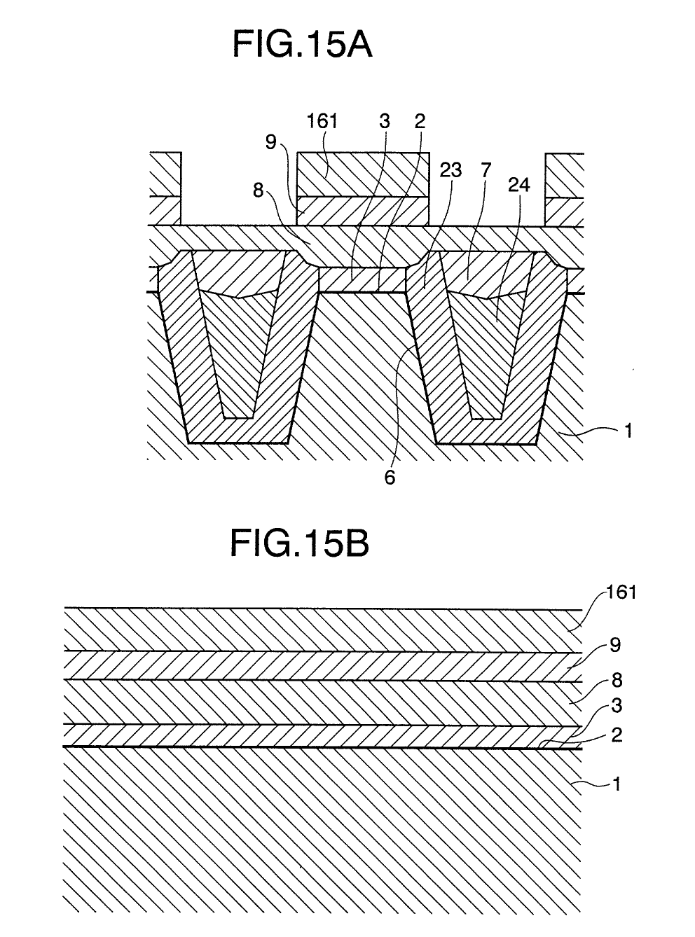

Next, a photoresist 161 is applied and is patterned to a predetermined pattern using the ordinary photo-etching technique, and, as shown in FIG. 15A and FIG. 15B, the silicon oxide film 9 is processed and removed with the patterned resist 16 used as a mask, for example, by the RIE method. Thereafter, the resist 16 is removed, for example, by the O₂ plasma treatment and using a mixed solution of sulfuric acid and a hydrogen peroxide solution.

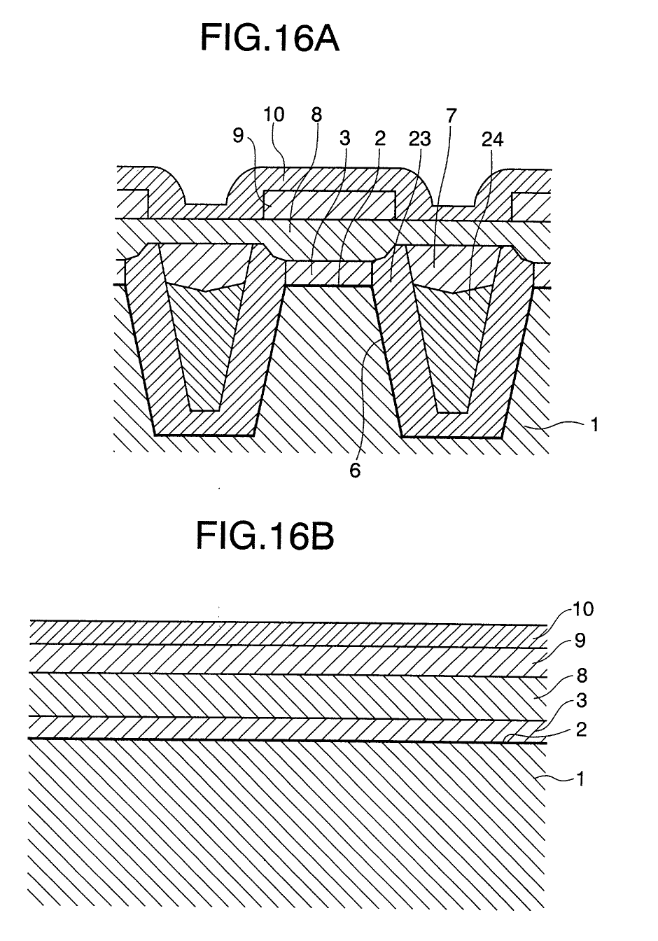

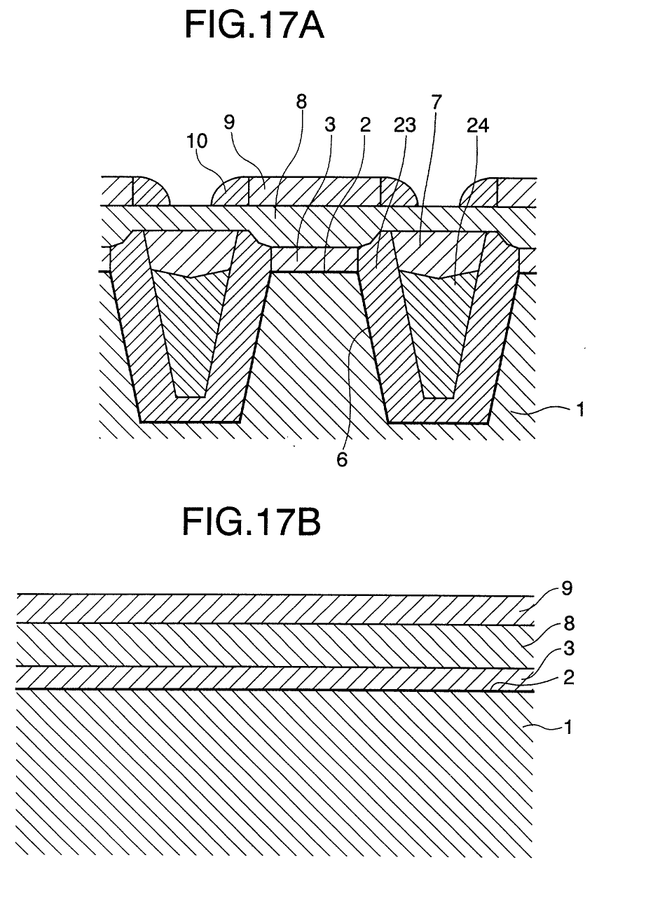

Next, as shown in FIG. 16A and FIG. 16B, a silicon oxide film 10 having a thickness of 70 nm is deposited, for example, by the pressure-reduced CVD method, and subsequently as shown in FIG. 17A and FIG. 17B, a predetermined mask material is formed on a surface layer using a whole-surface etch-back method.

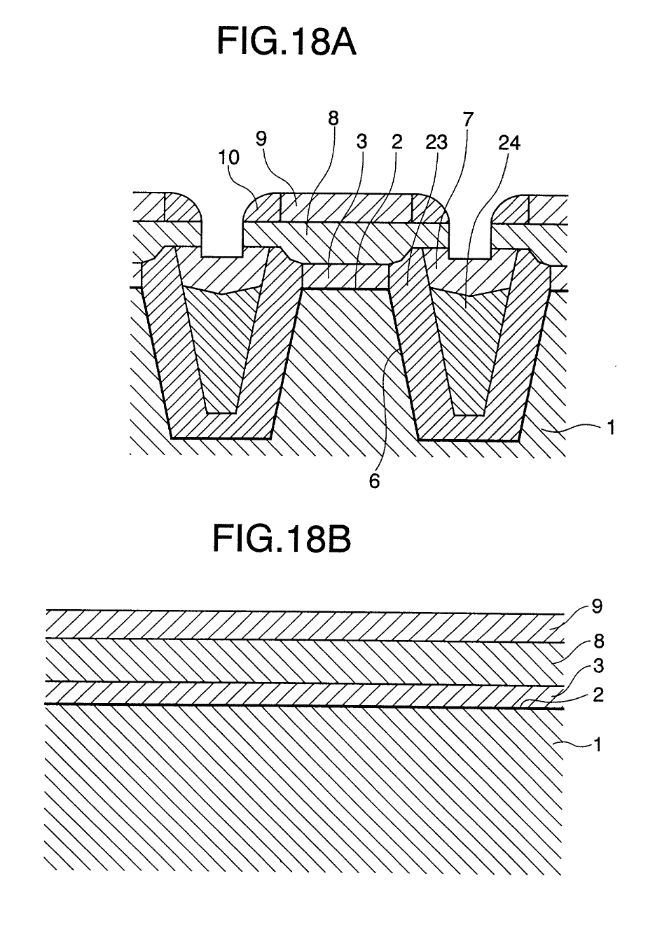

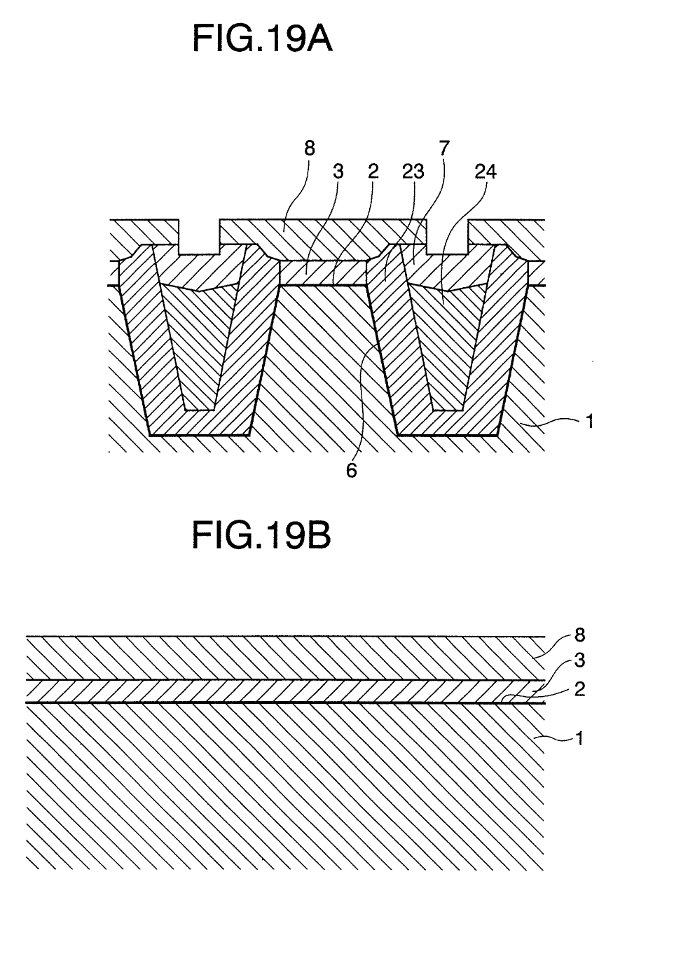

Next, using this mask material, the polycrystalline silicon film 8 on the trench is processed and removed, for example, by the RIE method. Furthermore, as shown in FIG. 18A and FIG. 18B, the silicon oxide film 7 on the trench is processed, utilizing the RIE method on the whole surface under the condition of a high selection ratio to the polycrystalline silicon film 8. Then, as shown in FIG. 19A and FIG. 19B, the silicon oxide films 9 and 10 are removed using, for example, the O₂ plasma treatment and a hydrofluoric acid treatment. Incidentally, a groove on the trench formed in the polycrystalline silicon film 8 is called a slit.

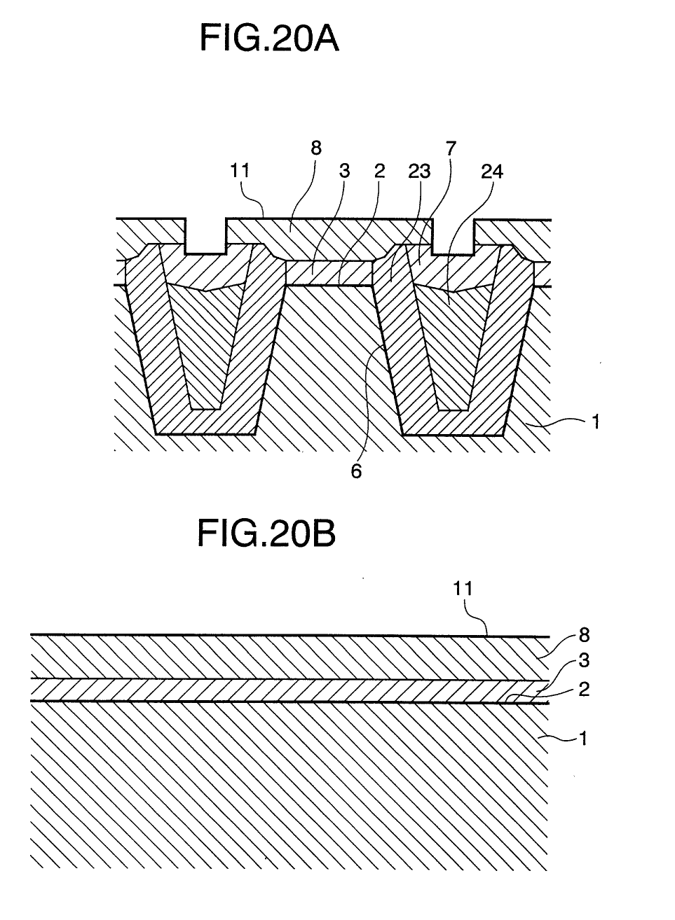

Next, as shown in FIG. 20A and FIG. 20B, the second gate insulation film 11 as an ONO (oxide: 5 nm, SiN: 7 nm, oxide: 5 nm) film having a thickness of 17 nm is formed on the polycrystalline silicon film 8, for example, by the pressure-reduced CVD method.

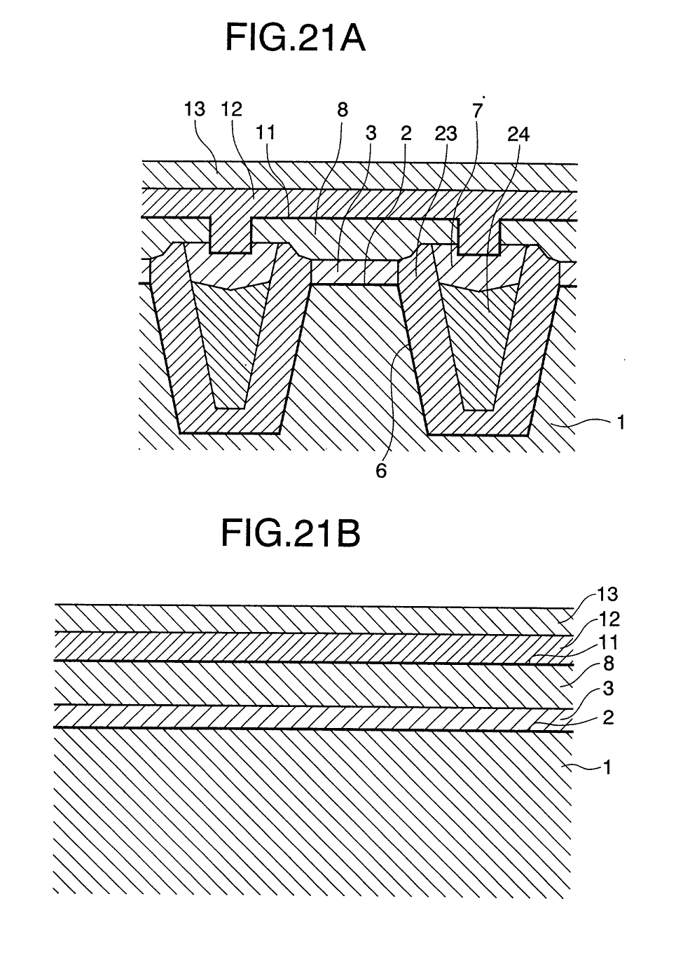

Thereafter, as shown in FIG. 21A and FIG. 21B, the polycrystalline silicon film 12 having a thickness of 80 nm is deposited, for example, by the pressure-reduced CVD method, and the tungsten silicide film 13 having a thickness of 50 nm is further deposited on it, for example, by a PVD method (physical vapor deposition method).

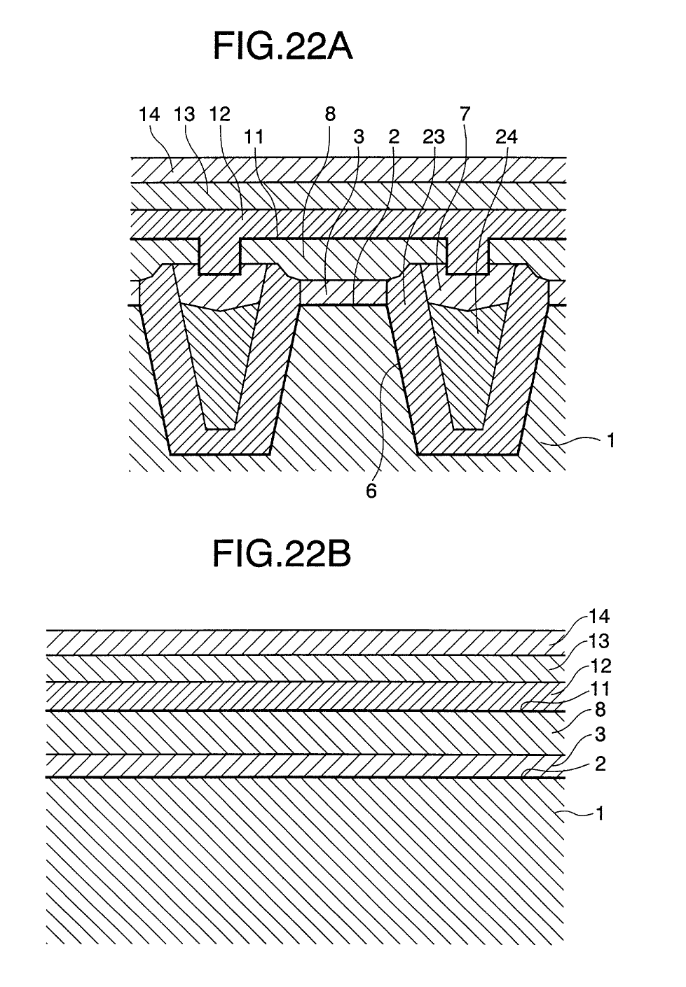

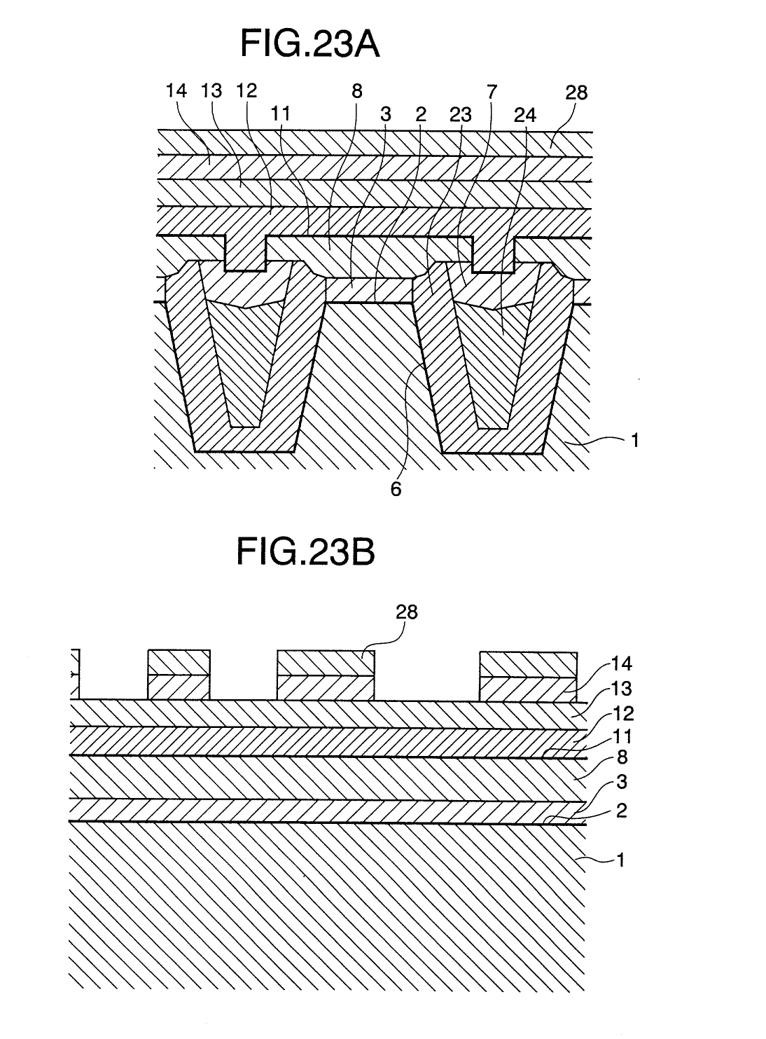

Next, as shown in FIG. 22A and FIG. 22B, the silicon oxide film 14 which works as a mask material for processing the second gate insulation film 11 and so on is subsequently deposited to be 230 nm in thickness, for example by the pressure-reduced CVD method. Then, a photoresist 28 is applied on it and patterned to a predetermined pattern by the ordinary photo-etching technique, and as shown in FIG. 23A and FIG. 23B, the silicon oxide film 14 is processed and removed, for example, by the RIE method with the patterned resist 28 used as a mask. Thereafter, the resist 28 is removed, for example, by the O₂ plasma treatment and using a mixed solution of sulfuric acid and a hydrogen peroxide solution.

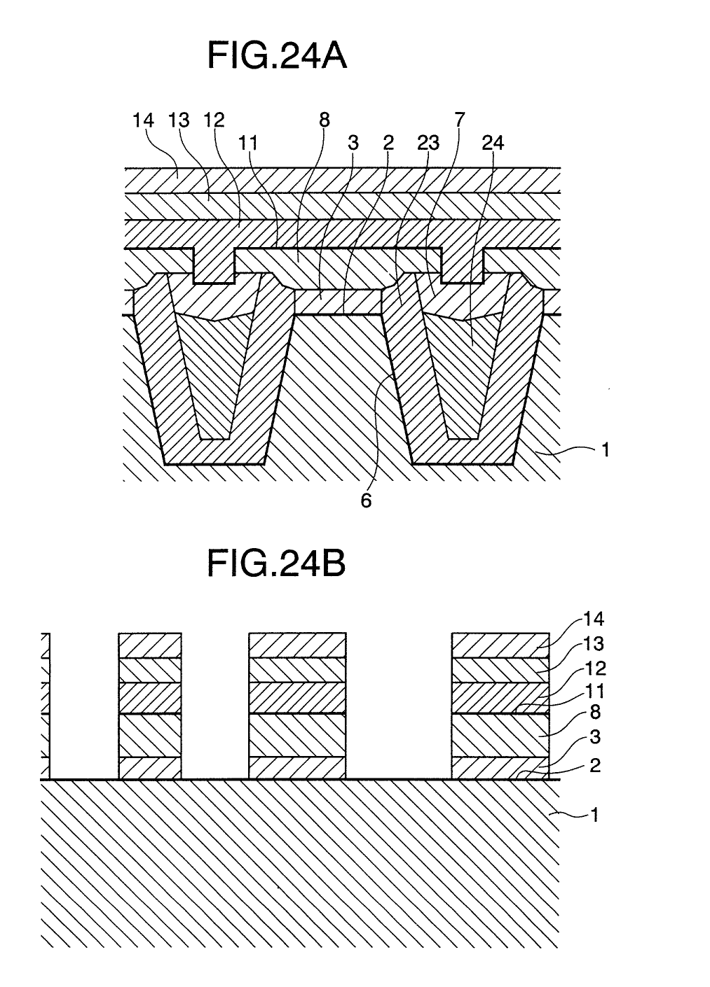

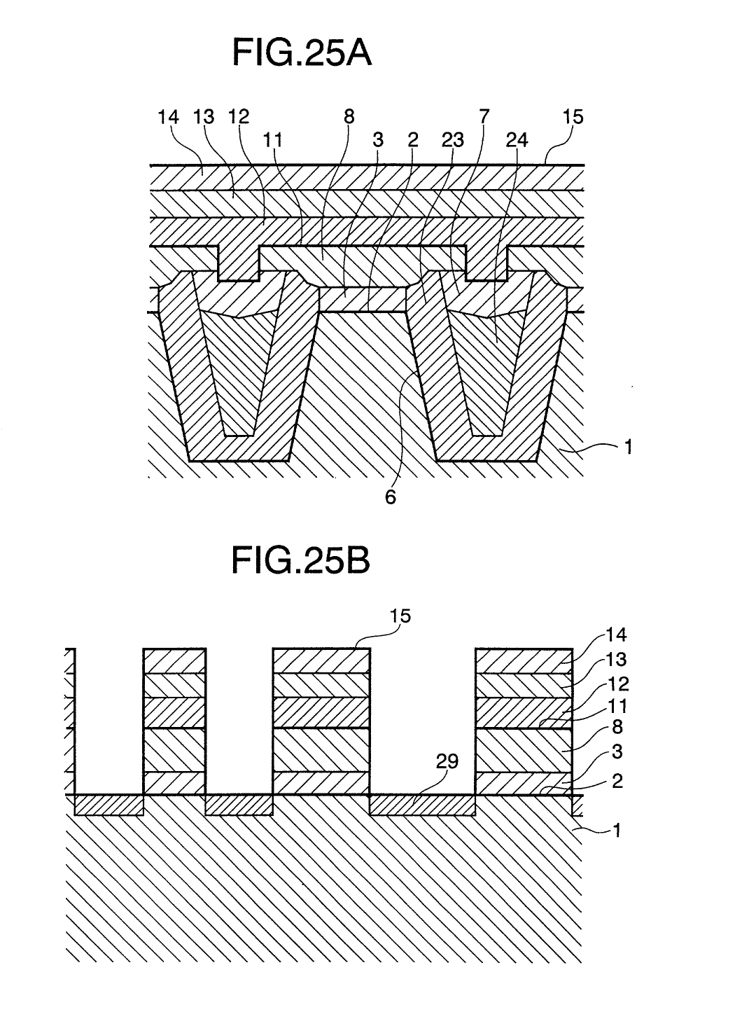

Next, as shown in FIG. 24A and FIG. 24B, the tungsten silicide film 13, the polycrystalline silicon film 12, the second gate insulation film 11, the polycrystalline silicon film 8, and the polycrystalline silicon film 3 are processed and removed, for example, by the RIE method, with the processed silicon oxide film 14 used as a mask. Furthermore, thermal processing in a nitride atmosphere is performed, for example, at 800° C. for 120 seconds and in addition, thermal processing in an oxide atmosphere at 100° C. is performed so that the silicon oxide film 15 having a thickness of 10 nm is formed on an exposed surface as shown in FIG. 25A and FIG. 25B. Thereafter, ion implantation to the semiconductor substrate 1 is performed via the silicon oxide film 15 to form the source/drain regions 29. Incidentally, the implanted ions are diffused so that portions of the source/drain regions 29 overlapping a lower surface of the first gate insulation film 2 are formed in a subsequent process.

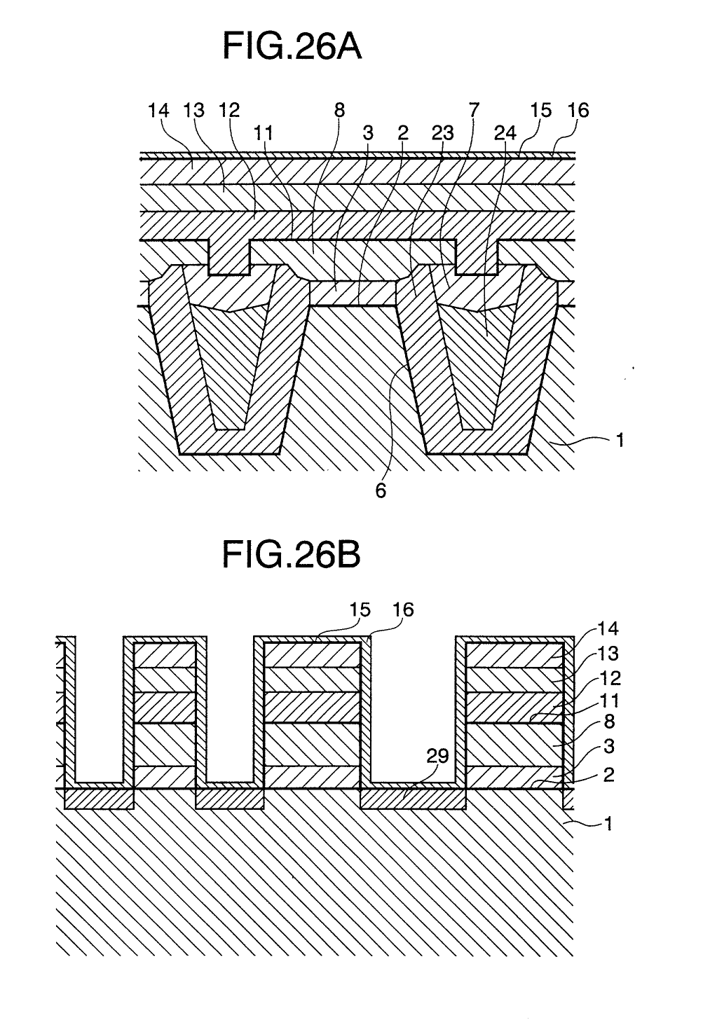

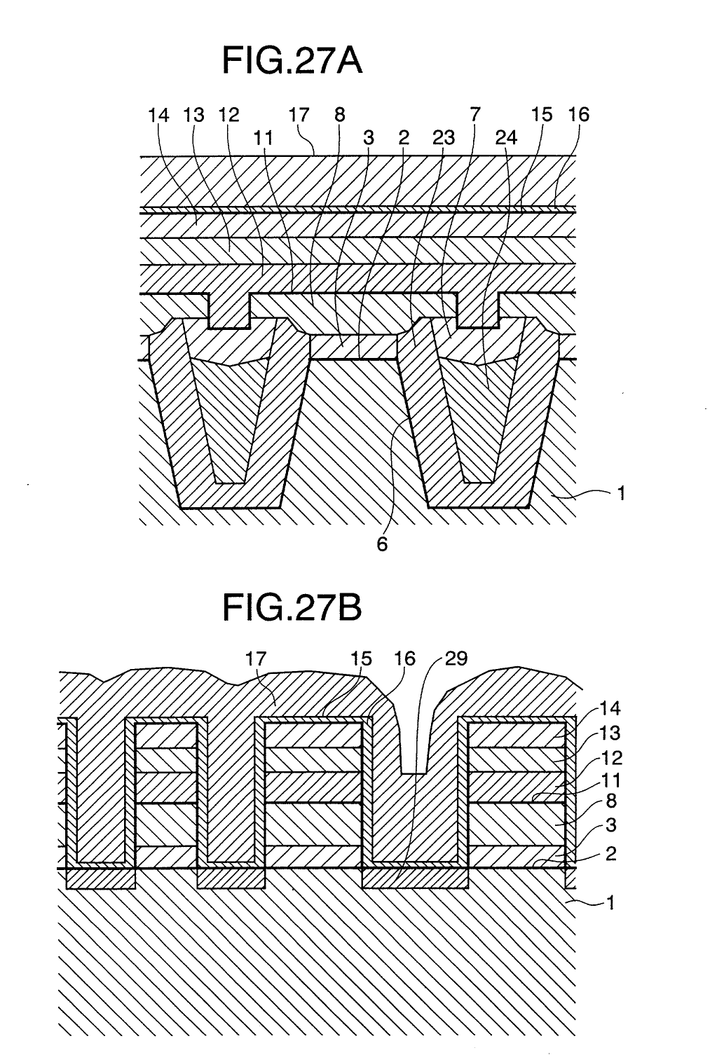

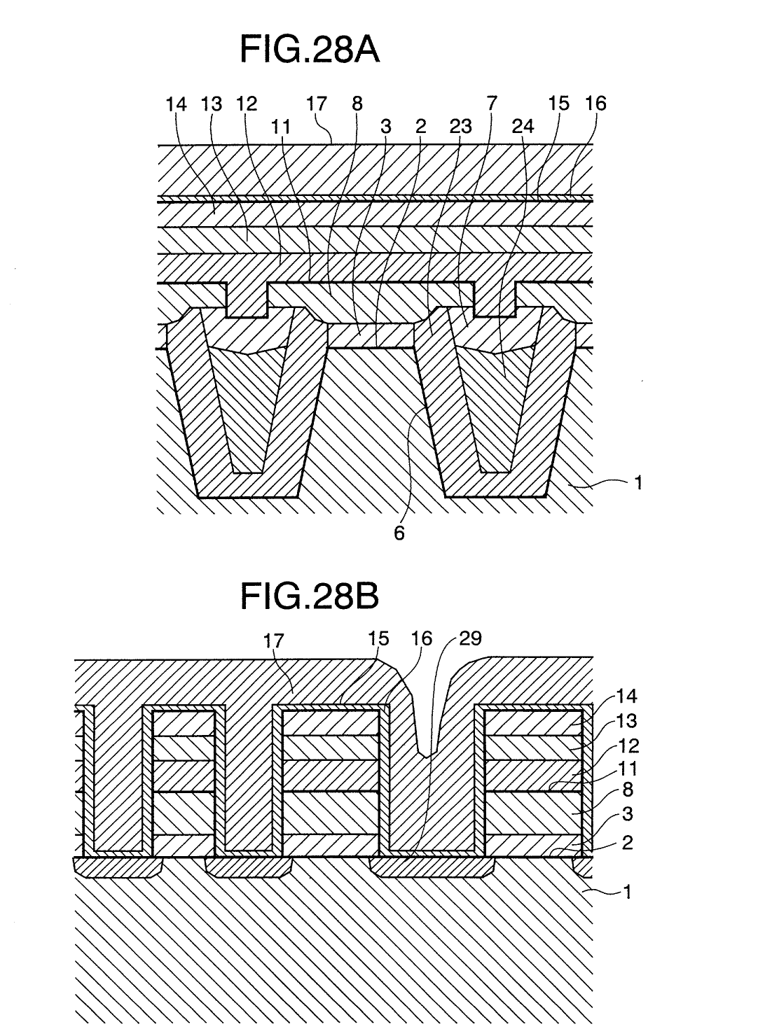

Next, as shown in FIG. 26A and FIG. 26B, the silicon nitride film 16 having a thickness of 40 nm is deposited on an exposed surface, for example, by the pressure-reduced CVD method. Then, as shown in FIG. 27A and FIG. 27B, the insulation film (BPSG film) 17 having a thickness of 300 nm is deposited on it, for example, by a normal-pressure CVD method, and thereafter, as shown in FIG. 28A and FIG. 28B, it is further made to reflow by thermal processing in a nitride atmosphere, for example, at 800° C. for 30 minutes.

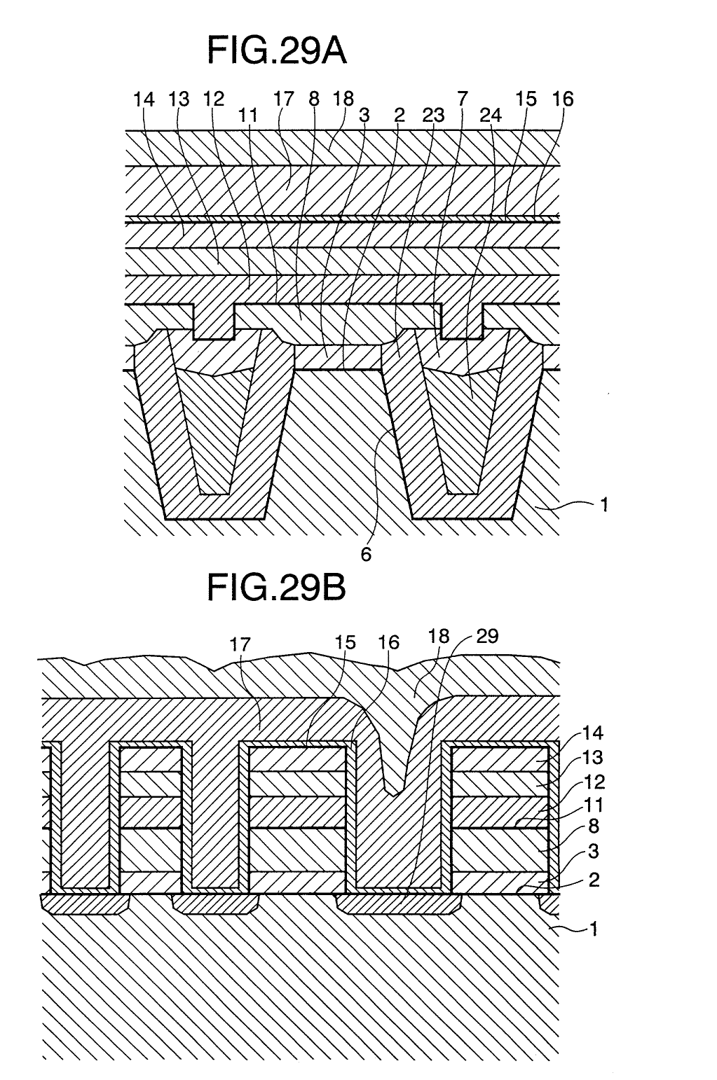

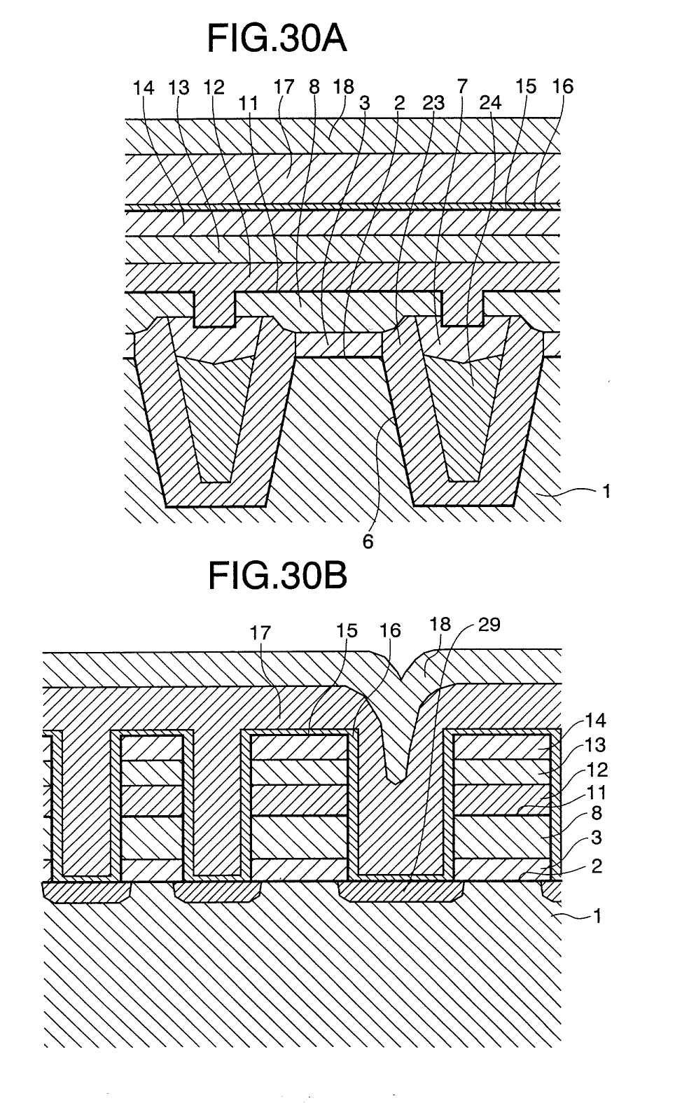

Next, as shown in FIG. 29A and FIG. 29B, an insulation film (BPSG film) 18 having a thickness of, for example, 300 nm is additionally deposited and is subsequently made to reflow by thermal processing in a nitride atmosphere, for example, at 800° C. for 30 minutes as shown in FIG. 30A and FIG. 30B. Incidentally, the thermal processing at the time of the reflowing of the insulation film (BPSG film) 17 and the thermal processing of the insulation film (BPSG film) 18 make it possible to controllably form the source/drain regions 29 overlapping the first gate insulation film 2.

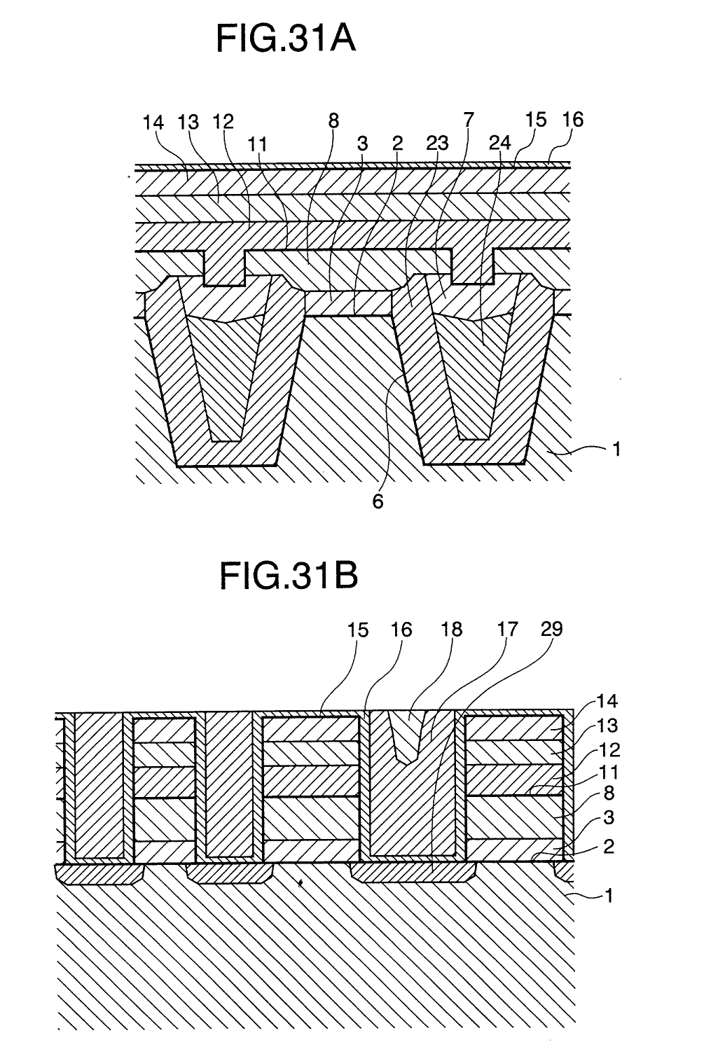

Next, as shown in FIG. 31A and FIG. 31B, the insulation film 17 and the insulation film 18 are shaved, for example, by the CMP method to be flattened so that the silicon nitride film 16 having a high selection ratio to the silicon oxide film is exposed. Thereafter, heating processing in a nitride atmosphere, for example, at 800° C. for 15 minutes is performed to flatten the surface of the insulation films 17 and 18, and heating processing in a nitride atmosphere, for example, at 950° C. for 10 seconds is subsequently performed.

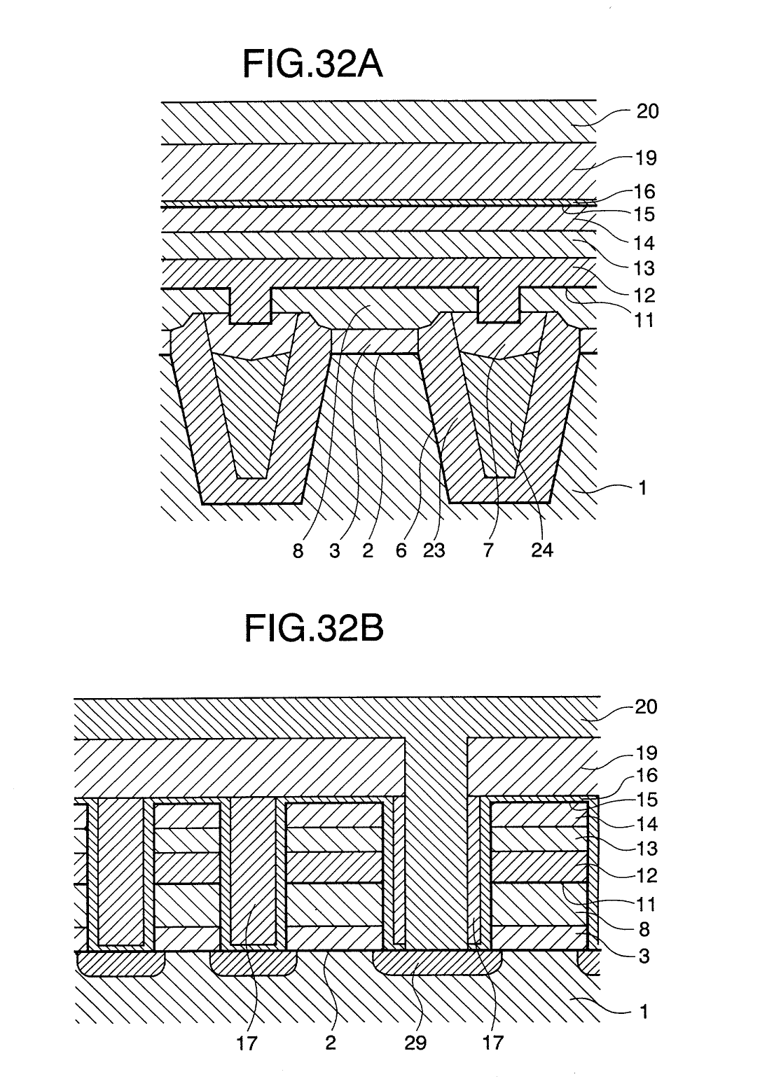

Next, the silicon oxide film 19 having a thickness of 350 nm is deposited, for example, by the plasma CVD method, a photoresist is applied on it and patterned to a predetermined pattern using the ordinary photo-etching technique, and the silicon oxide film 19, the insulation film 18, and the insulation film 17 are processed and removed, for example, by the RIE method with the patterned resist used as a mask so that a contact hole is formed on the silicon nitride film 16 on the semiconductor substrate 1. Thereafter, the photoresist is removed, for example, by the O₂ plasma treatment and using a mixed solution of sulfuric acid and a hydrogen peroxide solution. Furthermore, with the processed silicon oxide film 19 used as a mask, the silicon nitride film 16 on the bottom of the aforesaid contact hole is processed and removed, for example, using the RIE method until the source/drain region 29 is exposed. Then a substance produced on a side wall on a contact side is removed by the O₂ plasma treatment and using a mixed solution of sulfuric acid and a hydrogen peroxide solution. Thereafter, the polycrystalline silicon film 20 having a thickness of 300 nm is deposited, for example, by the pressure-reduced CVD method (refer to FIG. 32A and FIG. 32B for the above description in this paragraph). Incidentally, the contacts, though not shown, are also formed in necessary portions of the polycrystalline silicon film 8, the polycrystalline silicon film 12, and so on other than in the portion described above.

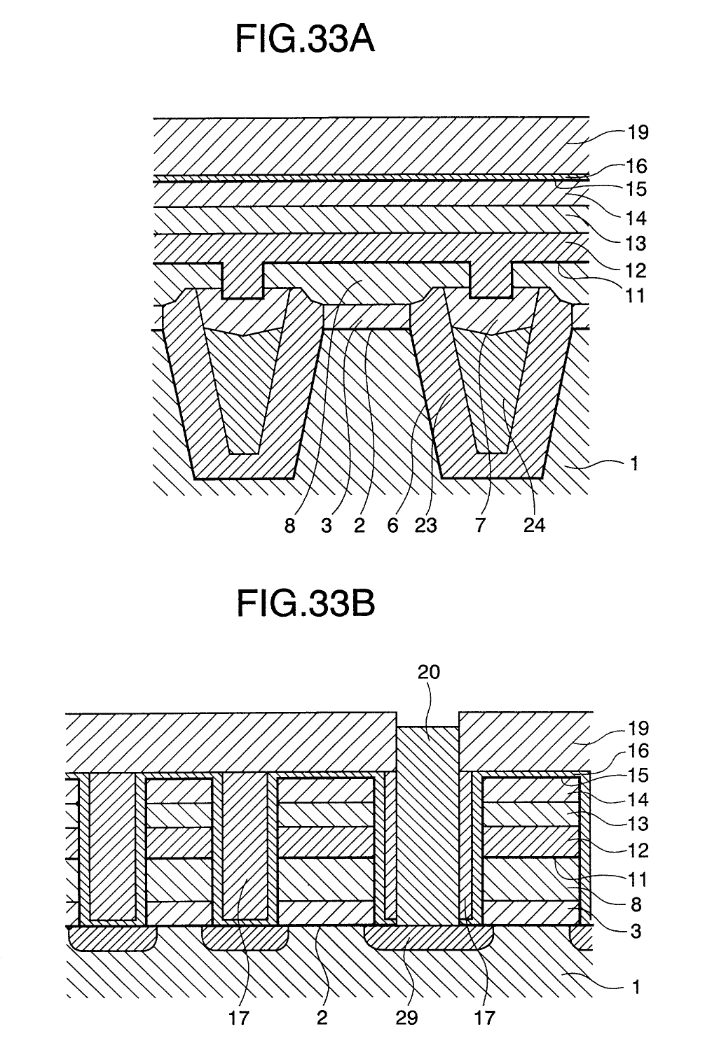

Next, as shown in FIG. 33A and FIG. 33B, the height of the deposited polycrystalline silicon film 20 is adjusted, for example, by the CDE method and thereafter, heating processing in a nitride atmosphere, for example, at 950° C. for 10 seconds is performed. Furthermore, a photoresist is applied on the surface and is patterned to a predetermined pattern using the ordinary photo-etching technique, and with the patterned resist used as a mask, the silicon oxide film 19 is processed using, for example, the RIE method. Thereafter, the resist is removed, for example, by the O₂ plasma treatment and using a mixed solution of sulfuric acid and a hydrogen peroxide solution.

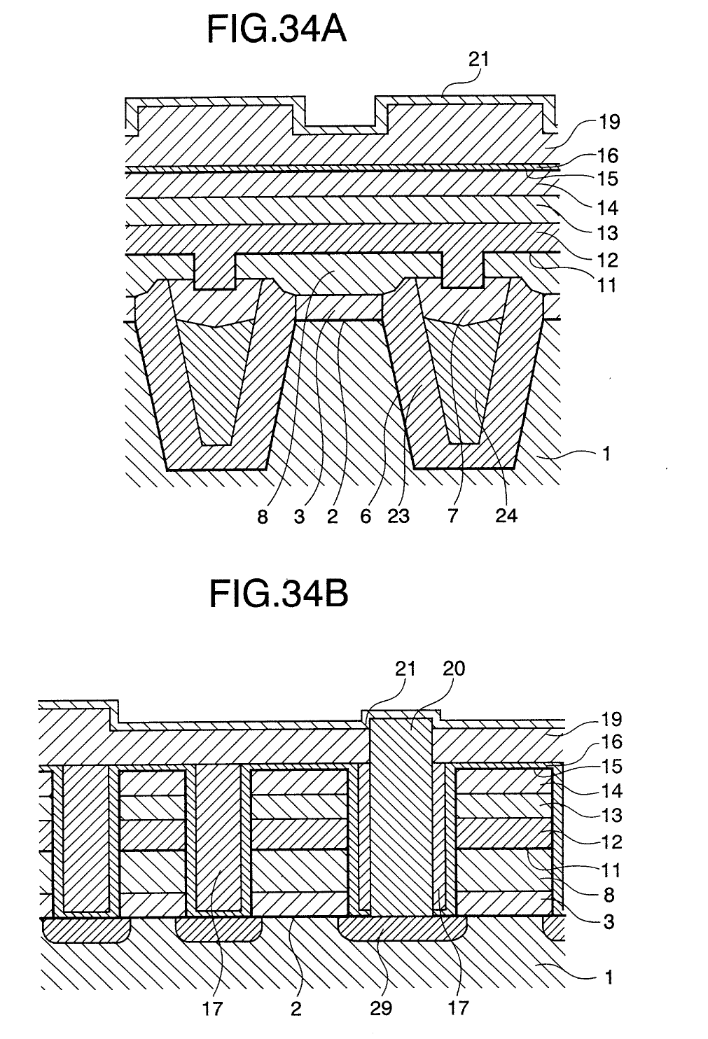

Next, as shown in FIG. 34A and FIG. 34B, the titanium film 21 having a thickness of 300 nm is deposited, for example, by the PVD method. Then, heating processing is performed, for example, in a mixed gas atmosphere of hydrogen and nitrogen at 550° C. for 90 minutes, and the tungsten film 22 is thereafter deposited, for example, by the PVD method. Further, the tungsten film 22 and the titanium film 21 are shaved, for example, by the CMP method to be flattened until the silicon film 19 is exposed. Heating processing is thereafter performed, for example, in a mixed gas atmosphere of hydrogen and nitrogen at 400° C. for 30 minutes. This makes it possible to realize the nonvolatile semiconductor memory device as shown in FIG. 2 and FIG. 3.

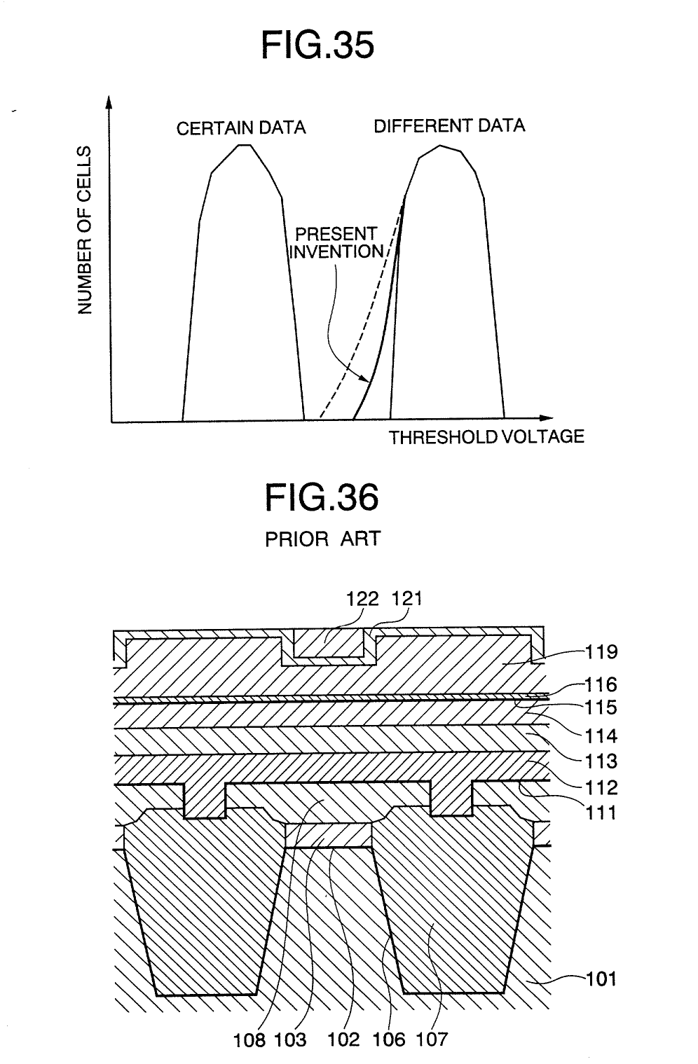

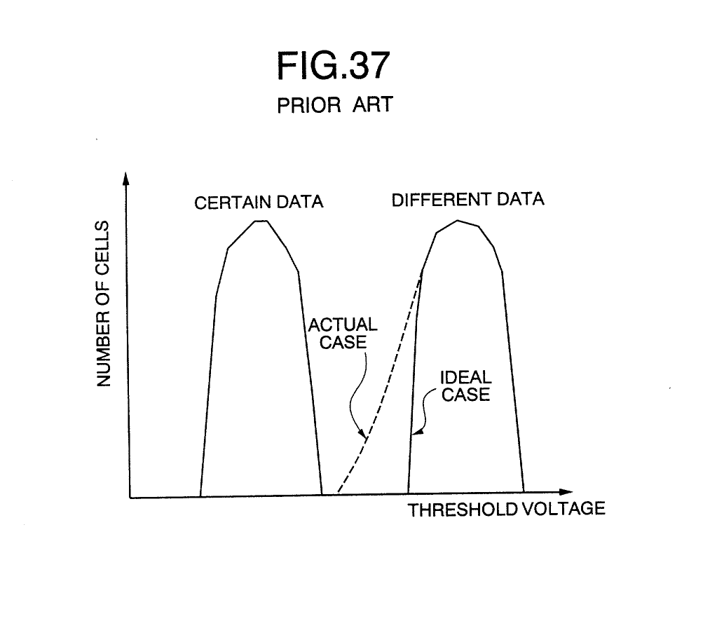

The semiconductor memory device manufactured through the manufacturing processes described above has a threshold voltage distribution characteristic that the distribution range can be suppressed to be narrow compared with that of a semiconductor memory device in a prior art, and as shown in FIG. 35, the distribution separated from that of a cell in a memory state of different data is realized, allowing a sufficient margin to this cell. FIG. 35 is a view showing, in comparison with the prior art, the threshold voltage distribution of the number of cells in the semiconductor memory device, which is the embodiment described above, having a plurality of cells. The range of the threshold voltage distribution of “different data” in FIG. 35 can be suppressed, for example, to about 0.7 V. This is a value smaller than that in the prior art by 0.1 V or more.

It should be understood that the present invention is not limited to the specific forms which are described here with reference to the drawings and that any modifications which come within the following claims are embraced therein.

What is claimed is:

1. A nonvolatile semiconductor memory device, comprising an element region having a plurality of memory cells and an element isolating region to electrically isolate the memory cells from each other,
wherein each of the memory cells comprises:
a channel region;
a gate insulation film formed on the channel region;
a floating gate electrode formed on the gate insulation film;
a second gate insulation film formed on the floating gate electrode;
a control gate electrode formed on the second gate insulation film; and
source/drain regions formed to sandwich the channel region in a horizontal direction, and
wherein the element isolating region comprises:
element isolating insulators formed to sandwich the channel region in a horizontal direction substantially perpendicular to the direction in which the source/drain regions sandwich the channel region; and
an electric conductor passing inside the element isolating insulator in a horizontal direction substantially parallel to the direction in which the source/drain regions sandwich the channel region.

2. A nonvolatile semiconductor memory device as set forth in claim 1,
wherein the floating gate electrode is capable of maintaining a held electric amount which is to form a memory state, in a manner that the held electric amount corresponds to three memory states or more.

3. A nonvolatile semiconductor memory device as set forth in claim 1, further comprising:
a contact to the electric conductor which is disposed in contact with the electric conductor and which is to apply a certain voltage to the electric conductor.

4. A nonvolatile semiconductor memory device as set forth in claim 1,
wherein the electric conductor is made to be a ground potential.

5. A nonvolatile semiconductor memory device as set forth in claim 1,
wherein the electric conductor is polycrystalline silicon of a fist conductivity type or a second conductivity type.

6. A nonvolatile semiconductor memory device as set forth in claim 1,
wherein the electric conductor is tungsten or aluminum.

7. A nonvolatile semiconductor memory device as set forth in claim 1,
wherein the electric conductor is metal silicide.

8. A nonvolatile semiconductor memory device as set forth in claim 1,
wherein the element isolating insulator is silicon oxide.

9. A nonvolatile semiconductor memory device as set forth in claim 1,
wherein the element isolating insulator is formed in a trench.

10. A manufacturing method of a nonvolatile semiconductor memory device, comprising:
forming on a semiconductor substrate an insulation film to be a gate insulation film;
forming a trench on the semiconductor substrate;
forming a second insulation film on a bottom wall and side walls of the formed trench;
forming an electric conductive film in the trench on which the second insulation film is formed;
forming a third insulation film to cover an upper surface of the electric conductive film;
forming on the insulation film a second electric conductive film to be a floating gate electrode;
forming on the second electric conductive film a fourth insulation film to be a second gate insulation film;
forming on the fourth insulation film a third electric conductive film to be a control gate electrode; and
forming source/drain regions under the insulation film.
